(19) United States
(12) Patent Application Publication
(10) Pub. No.: US 2025/0183937 A1
(43) Pub. Date: Jun. 5, 2025

(54) MULTIPLE SUBSCRIBER IDENTITY MODULE (MSIM) TRANSCEIVER

(71) Applicant: QUALCOMM Incorporated, San Diego, CA (US)

(72) Inventors: Mahim RANJAN, San Diego, CA (US); Saranyan NAGARAJAN, Hyderabad (IN); Ayush MITTAL, Bangalore (IN); Prasidh RAMABADRAN, Bangalore (IN); Sriramgopal SRIDHARA, San Diego, CA (US); Ehab ABDEL GHANY, San Diego, CA (US); Ranjit Kumar GUNTREDDI, Bangalore (IN); Karthik M B, Davanagere (IN); Krishnaswamy THIAGARAJAN, Bangalore (IN); Neeraj PUROHIT, Bengaluru (IN)

(21) Appl. No.: 18/525,399

(22) Filed: Nov. 30, 2023

(51) Int. Cl. H04B 1/44; H03F 3/19; H04W 88/06

(52) U.S. Cl. CPC H04B 1/44; H03F 3/19; H03F 2200/294; H03F 2200/451; H04W 88/06

(57) ABSTRACT

A system includes a first receive circuit coupled to a first antenna and a second receive circuit coupled to a second antenna. The first receive circuit includes a first low-noise amplifier coupled to the first antenna, and a first mixer coupled to the first low-noise amplifier. The second receive circuit includes a second low-noise amplifier coupled to the second antenna, and a second mixer coupled to the second low-noise amplifier. The system also includes a first frequency synthesizer configured to generate a first local oscillator (LO) signal, a second frequency synthesizer configured to generate a second LO signal, a first multiplexer configured to selectively couple the first LO signal or the second LO signal to the first mixer, and a second multiplexer configured to selectively couple the first LO signal or the second LO signal to the second mixer.

### BACKGROUND

### Field

Aspects of the present disclosure relate generally to wireless communications, and, more particularly, to multiple subscriber identity module (MSIM) wireless devices.

### Background

A wireless device may include one or more transceivers and multiple antennas for transmitting and/or receiving radio frequency (RF) signals. The wireless device may include multiple subscriber identity modules (SIMs) where each SIM is associated with a different subscriber.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a system for wireless communications. The system includes a first receive circuit coupled to a first antenna and a second receive circuit coupled to a second antenna. The first receive circuit includes a first low-noise amplifier coupled to the first antenna, and a first mixer coupled to the first low-noise amplifier. The second receive circuit includes a second low-noise amplifier coupled to the second antenna, and a second mixer coupled to the second low-noise amplifier. The system also includes a first frequency synthesizer configured to generate a first local oscillator (LO) signal, a second frequency synthesizer configured to generate a second LO signal, a first multiplexer configured to selectively couple the first LO signal or the second LO signal to the first mixer, and a second multiplexer configured to selectively couple the first LO signal or the second LO signal to the second mixer.

A second aspect relates to a method of operating a wireless device. The method includes, in a first configuration, receiving a first copy of a first radio frequency (RF) signal via a first antenna, receiving a second copy of the first RF signal via a second antenna, and generating a combined signal based on the first copy of the first RF signal and the second copy of the first RF signal. The method also includes, in a second configuration, receiving a second RF signal via the first antenna, receiving a third RF signal via the second antenna, recovering data or control information for a first subscriber based on the second RF signal, and recovering data or control information for a second subscriber based on the third RF signal.

A third aspect relates to an apparatus. The apparatus includes means for receiving a first copy of a first radio frequency (RF) signal via a first antenna, means for receiving a second copy of the first RF signal via a second antenna, and means for generating a combined signal based on the first copy of the first RF signal and the second copy of the first RF signal. The apparatus also includes means for receiving a second RF signal via the first antenna, means for receiving a third RF signal via the second antenna, means for recovering data or control information for a first subscriber based on the second RF signal, and means for recovering data or control information for a second subscriber based on the third RF signal.

A fourth aspect relates to a system for wireless communications. The system includes a first receive circuit coupled to a first antenna, wherein the first receive circuit is configured to receive a first copy of a first radio frequency (RF) signal via the first antenna, and receive a second RF signal via the first antenna. The system also includes a second receive circuit coupled to a second antenna, wherein the second receive circuit is configured to receive a second copy of the first RF signal via the second antenna, and receive a third RF signal via the second antenna. The system further includes a processor coupled to the first receive circuit and the second receive circuit, wherein the processor is configured to generate a combined signal based on the first copy of the first RF signal and the second copy of the first RF signal, recover data or control information for a first subscriber based on the second RF signal, and a recover data or control information for a second subscriber based on the third RF signal.

### BRIEF DESCRIPTION OF THE DRAWINGS

FIG. 1 is a diagram of an environment including a first base station, a second base station, and a wireless device that includes a transceiver according to certain aspects of the present disclosure.

FIG. 2 shows an exemplary implementation of the wireless device of FIG. 1 according to certain aspects of the present disclosure.

FIG. 3 shows an example of a diversity transceiver according to certain aspects of the present disclosure.

FIG. 4 shows an example of circuitry for operating the diversity transceiver of FIG. 3 in different configurations according to certain aspects of the present disclosure.

FIG. 5A shows an example of the wireless device including gating circuits for increasing isolation between a first local oscillator (LO) signal and a second LO signal according to certain aspects of the present disclosure.

FIG. 5B shows an exemplary implementation of the gating circuits according to certain aspects of the present disclosure.

FIG. 6 shows an example of the wireless device including drivers for driving mixers with the first LO signal and the second LO signal according to certain aspects of the present disclosure.

FIG. 7 shows an exemplary implementation of a first frequency synthesizer according to certain aspects of the present disclosure.

FIG. 8 shows an example of a cross switch for supporting antenna switched diversity according to certain aspects of the present disclosure.

FIG. 9A shows an example of the wireless device including receive circuits and transmit circuits according to certain aspects of the present disclosure.

FIG. 9B shows an example of the wireless device of FIG. 9A further including a cross switch according to certain aspects of the present disclosure.

FIG. 10A shows another example of the wireless device including receive circuits and transmit circuits according to certain aspects of the present disclosure.

FIG. 10B shows an example of the wireless device of FIG. 10A further including a cross switch according to certain aspects of the present disclosure.

FIG. 10C shows an example of a transceiver including a primary receive port and a diversity receive port according to certain aspects of the present disclosure.

FIG. 10D shows another example of a transceiver including a primary receive port and a diversity receive port according to certain aspects of the present disclosure.

FIG. 11 is a flowchart illustrating a method for operating a wireless device according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

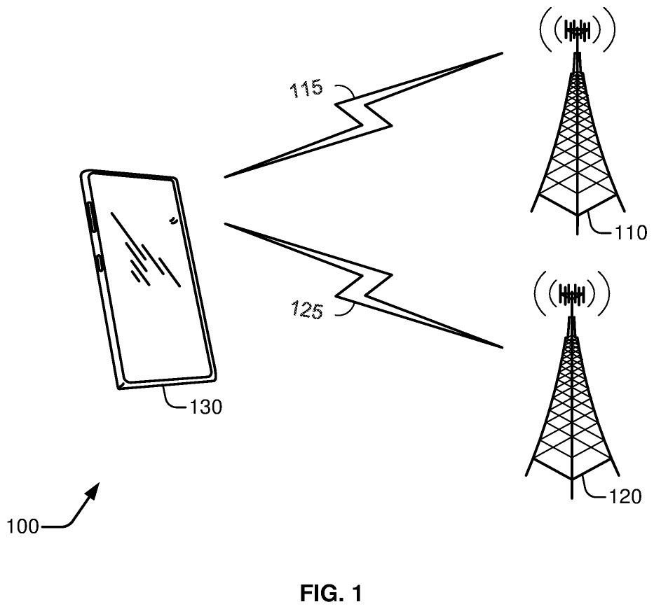

FIG. 1 is a diagram of an environment 100 that includes a wireless device 130, a first base station 110, and a second base station 120. Each of the base stations 110 and 120 may include or may be referred to as an access point, a NodeB, a next-generation Node B (also referred to as a gNB or gNodeB), a Home NodeB (also referred to as HNB), or some other terminology. The wireless device 130 may also be referred to as a mobile device, a remote device, user equipment (UE), a handheld device, or some other terminology. The wireless device 130 may include a cellular phone, a gaming device, a navigation device, a smart appliance, an Internet of Things (IoT) device, a tablet computer, an asset tracker, a sensor or security device, a laptop computer, or the like.

In the environment 100, the wireless devices 130 may communicate with the first base station 110 via a first wireless link 115, which may include a downlink of data and/or control information transmitted from the first base station 110 to the wireless device 130 and an uplink of other data and/or control information transmitted from the wireless device 130 to the first base station 110. The wireless devices 130 may also communicate with the second base station 120 via a second wireless link 125, which may include a downlink of data and/or control information transmitted from the second base station 120 to the wireless device 130 and an uplink of other data and/or control information transmitted from the wireless device 130 to the second base station 120. Each of the wireless links 115 and 125 may be implemented using any suitable communication protocol or standard, such as 3rd Generation Partnership Project Long-Term Evolution (3GPP LTE, 3GPP NR 5G), IEEE 1302.13, IEEE 1302.13, Bluetooth™, and so forth.

In certain aspects, the wireless device 130 may be a multi-subscriber identity module (multi-SIM) wireless device that supports communication using multiple SIMs where each SIM may be associated with a different subscriber. In these aspects, the wireless device 130 may communicate with the first base station 110 using a first SIM associated with a first subscriber and communicate with the second base station 120 using a second SIM associated with a second subscriber, as discussed further below. In these aspects, the first base station 110 and the second base station 120 may be associated with different carrier networks or the same carrier network.

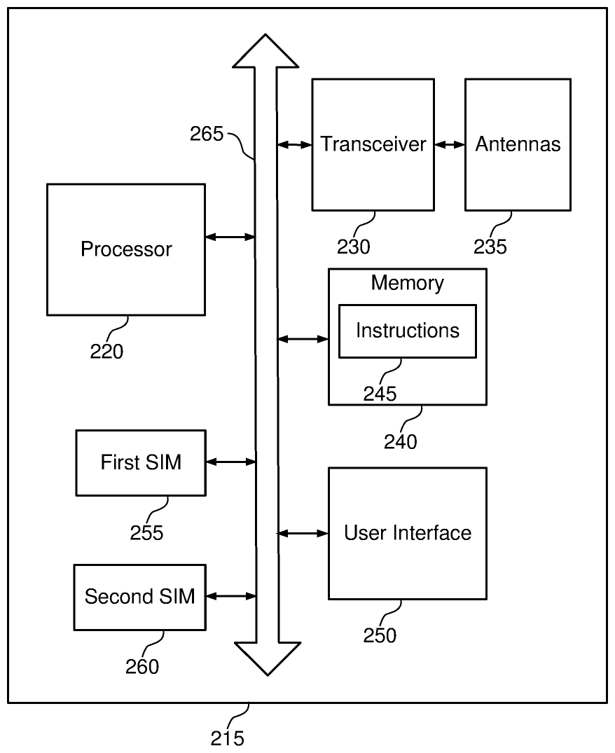

FIG. 2 is a block diagram showing an exemplary implementation of the wireless device 130 according to aspects of the present disclosure. In this example, the wireless device 130 includes a processor 220, a memory 240, a transceiver 230, antennas 235, a user interface 250, a first SIM 255, and a second SIM 260. These components may be in electronic communication via one or more buses 265.

The memory 240 may store instructions 245 that are executable by the processor 220 to cause the wireless device 130 to perform one or more of the operations described herein. The processor 220 may include a general-purpose processor, a modem, a baseband processor, a digital signal processor (DSP), a central processing unit (CPU), a microcontroller, an application specific integrated circuit (ASIC), a field programmable gate array (FPGA), a programmable logic device, a discrete gate or transistor logic component, a discrete hardware component, or any combination thereof. The memory 240 may include, by way of example, random access memory (RAM), flash memory, read only memory (ROM), programmable read only memory (PROM), erasable programmable read only memory (EPROM), electrically erasable programmable read only memory (EEPROM), registers, magnetic disks, optical disks, hard drives, or any other suitable storage medium, or any combination thereof.

The transceiver 230 is configured to communicate with base stations (e.g., the first base station 110 and the second base station 120) via the antennas 235. More particularly, the transceiver 230 is configured to transmit signals to the base stations and receive signals from the base stations via the antennas 235, as discussed further below.

The user interface 250 may be configured to receive data from a user (e.g., via keypad, mouse, touchscreen, etc.) and provide the data to the processor 220. The user interface 250 may also be configured to output data from the processor 220 to the user (e.g., via a display, a speaker, etc.).

In certain aspects, the first SIM 255 includes memory (e.g., in a removable integrated circuit card) that stores an international mobile subscriber identity (IMSI), user account information, authentication information, and/or other information used to identify and/or authenticate a first subscriber with a network. The first subscriber may have a subscription for one or more services (e.g., data services, voice services, IMS services, etc.) on the network. In one example, the wireless device 130 transmits the IMSI and the authentication information for the first subscriber to the first base station 110 to access the network (e.g., carrier network) via the first base station 110 as the first subscriber,

The second SIM 260 includes memory (e.g., in a removable integrated circuit card) that stores an IMSI, user account information, authentication information, and/or other information used to identify and/or authenticate a second subscriber with the same network as the first SIM 255 or a different network. The second subscriber may have a subscription for one or more services (e.g., data services, voice services, IMS services, etc.) on the network. In one example, the wireless device 130 transmits the IMSI and the authentication information for the second subscriber to the second base station 120 to access the network (e.g., carrier network) via the second base station 120 as the second subscriber. In another example, the wireless device 130 transmits the IMSI and the authentication information for the second subscriber to the first base station 110 to access the network (e.g., carrier network) via the first base station 110 as the second subscriber (e.g., for the case where the first subscriber and the second subscriber have subscription with the same carrier network).

The first and second subscribers may have subscriptions with the same carrier network or different carrier networks. Also, the first and second subscribers may have subscriptions for the same services and/or different services.

The wireless device 130 may support one or more modes of operations for multiple subscribers. For example, the wireless device 130 may support a dual SIM dual standby (DSDS) mode, in which one of the subscribers may actively receive and transmit signals via the transceiver 230 at a time while the other subscriber may be put on standby. In another example, the wireless device 130 may support a dual SIM dual active (DSDA) mode, in which both subscribers may actively receive and transmit signals via the transceiver 230 at the same time. It is to be appreciated that the present disclosure is not limited to the above examples.

The transceiver 230 may include multiple transceivers to support multiple subscribers. However, as discussed further below, it is desirable to share one or more transceivers among multiple subscribers (e.g., the first subscriber and the second subscriber) to reduce area and cost.

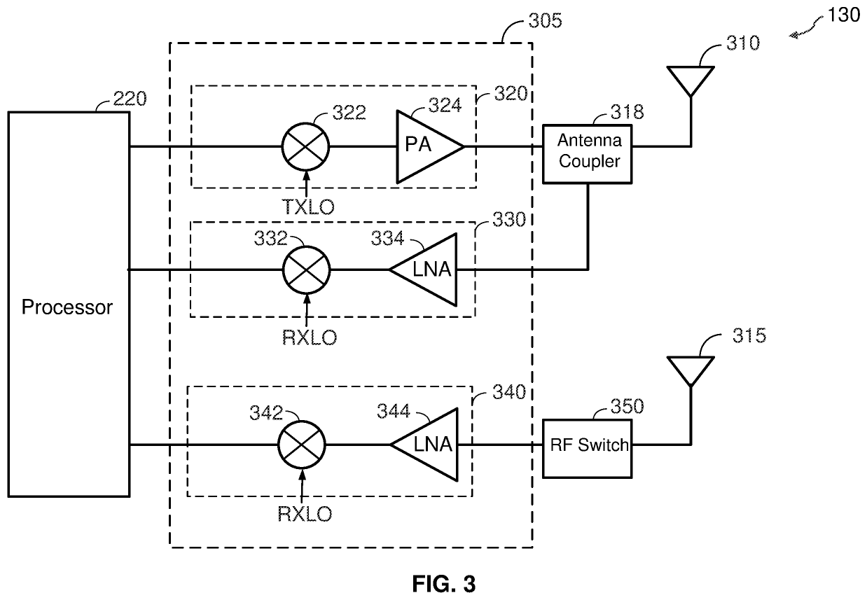

In certain aspects, the wireless device 130 may employ antenna diversity to improve the quality and reliability of a wireless link (e.g., the first wireless link 115 or the second wireless link 125). In this regard, FIG. 3 shows an example of a diversity transceiver 305 configured to receive signals using antenna diversity according to certain aspects. The diversity transceiver 305 may be included in the transceiver 230 shown in FIG. 2.

In this example, the antennas 235 in FIG. 2 include a first antenna 310 and a second antenna 315. The first antenna 310 and the second antenna 315 may be physically spaced apart on the wireless device 130. The first antenna 310 and the second antenna 315 may be orientated in different directions or the same direction.

The diversity transceiver 305 includes a transmit circuit 320, a first receive circuit 330, and a second receive circuit 340. The first receive circuit 330 may be referred to as a primary receive circuit, and the second receive circuit 340 may be referred to as a secondary or diversity receive circuit. In this example, the transmit circuit 320 and the first receive circuit 330 are coupled to the first antenna 310 via an antenna coupler 318. The antenna coupler 318 may include a duplexer, a diplexer, switches, or another type of antenna coupler configured to couple a transmit circuit and a receive circuit to a shared antenna. The second receive circuit 340 may be coupled to the second antenna 315 through an RF switch 350 allows the second antenna 315 to be selectively coupled to the second receive circuit 340. The RF switch 350 may also allow the second antenna 315 to be selectively coupled to one or more other receive circuits and/or transmitters (not shown).

In the example in FIG. 3, the transmit circuit 320 is coupled between the processor 220 and the antenna coupler 318 (e.g., duplexer), and the first receive circuit 330 is coupled between the processor 220 and the antenna coupler 318. The second receive circuit 340 is coupled between the second antenna 315 and the processor 220 (e.g., through the RF switch 350). In this example, the processor 220 may include a baseband processor and/or a radio defined software.

In this example, the transmit circuit 320 includes a transmit mixer 322 and a power amplifier 324. The transmit mixer 322 may be configured to receive a baseband signal or an intermediate frequency (IF) signal, and mix the baseband signal or the IF signal with a transmit local oscillator (TXLO) signal to frequency upconvert the baseband signal or the IF signal into a transmit radio frequency (RF) signal. The power amplifier 324 is configured to amplify the transmit RF signal, and output the amplified RF signal to the antenna coupler 318 (e.g., duplexer) for transmission via the first antenna 310. It is to be appreciated that the transmit circuit 320 may include one or more additional components not shown in FIG. 3. For example, the transmit circuit 320 may include a digital-to-analog converter (DAC) configured to convert a digital signal from the processor 220 into the baseband signal, one or more filters, one or more amplifiers, etc. For the example where the transmit mixer 322 received an IF signal, the transmit circuit 320 may include another mixer (not shown) preceding the mixer 322 for frequency upconverting the baseband signal into the IF signal. In some implementations, the mixer 322 and the power amplifier 324 are integrated on the same chip. In other implementations, the mixer 322 is integrated on a chip and the power amplifier 324 is an off-chip (i.e., external) component. In these implementations, the chip may include a driver (not shown) between the mixer 322 and the power amplifier 324 for driving the power amplifier 324 with the RF signal.

In this example, the first receive circuit 330 (also referred to as the primary receive circuit) includes a first low-noise amplifier 334 and a first receive mixer 332. The first low-noise amplifier 334 is configured to receive an RF signal from the first antenna 310 via the antenna coupler 318, amplify the received RF signal, and output the amplified RF signal to the first receive mixer 332. The first receive mixer 332 may be configured to mix the amplified RF signal with a receive local oscillator (RXLO) signal to frequency downconvert the amplified RF signal into a baseband signal or an IF signal. It is to be appreciated that the first receive circuit 330 may include one or more additional components not shown in FIG. 3. For example, the first receive circuit 330 may include one or more amplifiers, one or more filters, and an analog-to-digital converter (ADC) configured to convert the baseband signal into a digital signal and output the digital signal to the processor 220 for further processing (e.g., demodulation, decoding, etc.). For the example where the first receive mixer 332 converts the amplified RF signal into the IF signal, the first receive circuit 330 may include another mixer (not shown) after the first receive mixer 332 for frequency downconverting the IF signal into the baseband signal. In some implementations, the mixer 332 and the low-noise amplifier 334 are integrated on the same chip. In other implementations, the mixer 332 is integrated on a chip and the low-noise amplifier 334 is an off-chip (i.e., external) component. In these implementations, the chip may include an amplifier (not shown) between the low-noise amplifier 334 and the mixer 332.

In this example, the second receive circuit 340 (also referred to as the secondary receive circuit) includes a second low-noise amplifier 344 and a second receive mixer 342. The second low-noise amplifier 344 is configured to receive an RF signal from the second antenna 315, amplify the received RF signal, and output the amplified RF signal to the second receive mixer 342. The second receive mixer 342 may be configured to mix the amplified RF signal with the receive local oscillator (RXLO) signal to frequency downconvert the amplified RF signal into a baseband signal or an IF signal. It is to be appreciated that the second receive circuit 340 may include one or more additional components not shown in FIG. 3. For example, the second receive circuit 340 may include one or more amplifiers, one or more filters, and an ADC configured to convert the baseband signal into a digital signal and output the digital signal to the processor 220 for further processing (e.g., demodulation, decoding, etc.). For the example where the second receive mixer 342 converts the amplified RF signal into the IF signal, the second receive circuit 340 may include another mixer (not shown) after the second receive mixer 342 for frequency downconverting the IF signal into the baseband signal.

It is to be appreciated that, in some implementations, each of the mixers 322, 332, and 342 shown in FIG. 3 may be implemented with in-phase/quadrature (I/Q) mixers. For example, the first receive mixer 332 may be implemented with an I/Q mixer including a first mixer that mixes the respective RF signal with the RXLO signal to generate an in-phase baseband or IF signal, and a second mixer that mixes the respective RF signal with the RXLO signal shifted by 90 degrees to generate a quadrature baseband or IF signal. The second receive mixer 342 may also be implemented with an I/Q mixer in a similar manner. However, it is to be appreciated that the present disclosure is not limited to this example.

In operation, the wireless device 130 may use the diversity transceiver 305 to communicate with the first base station 110 using antenna diversity for reception. To transmit data and/or control information to the first base station 110, the processor 220 may process the data and/or control information into a digital baseband signal. The processing performed by the processor 220 may include modulation, coding, etc. The transmit circuit 320 may then convert the digital baseband signal into an RF signal and transmit the RF signal to the first base station via the first antenna 310.

To receive an RF signal transmitted from the first base station 110 using antenna diversity, the first antenna 310 receives a first copy of the RF signal and the second antenna 315 receives a second copy of the RF signal. Because the first antenna 310 and the second antenna 315 are spaced apart and/or orientated in different directions, the first copy of the RF signal and the second copy of the RF signal may experience different levels of fading, interference, etc. In some cases, the first copy of the RF signal and the second copy of the RF may travel along different paths from the first base station 110 to the respective antenna (i.e., the RF signal may travel along multiple paths from the first base station 110 to the wireless device 130).

The first receive circuit 330 converts the first copy of the RF signal into a first baseband signal and outputs the first baseband signal to the processor 220. The second receive circuit 340 converts the second copy of the RF signal into a second baseband signal and outputs the second baseband signal to the processor 220. The processor 220 combines the first baseband signal and the second baseband signal into a combined signal to provide diversity gain (e.g., to increase signal-to-interference ratio). The processor 220 may employ one or more combining techniques known in the art to combine the first baseband signal and the second baseband signal including maximal ratio combining, minimum mean square error, equal-gain combining, active null steering, and/or another combining technique. The processor 220 may then process the combined signal to recover data and/or control information. For example, the processor 220 may perform demodulation, decoding, and/or other operations on the combined signal to recover the data and/or control information.

In certain aspects, the transceiver 230 may include a separate instance of the diversity transceiver 305 for each of the first subscriber and the second subscriber discussed above. However, providing a separate instance of the diversity transceiver 305 for each subscriber increases area and cost.

To address this, aspects of the present disclosure allow multiple subscribers (e.g., the first subscriber and the second subscriber) to share one or more diversity transceivers to reduce area and cost, as discussed further below.

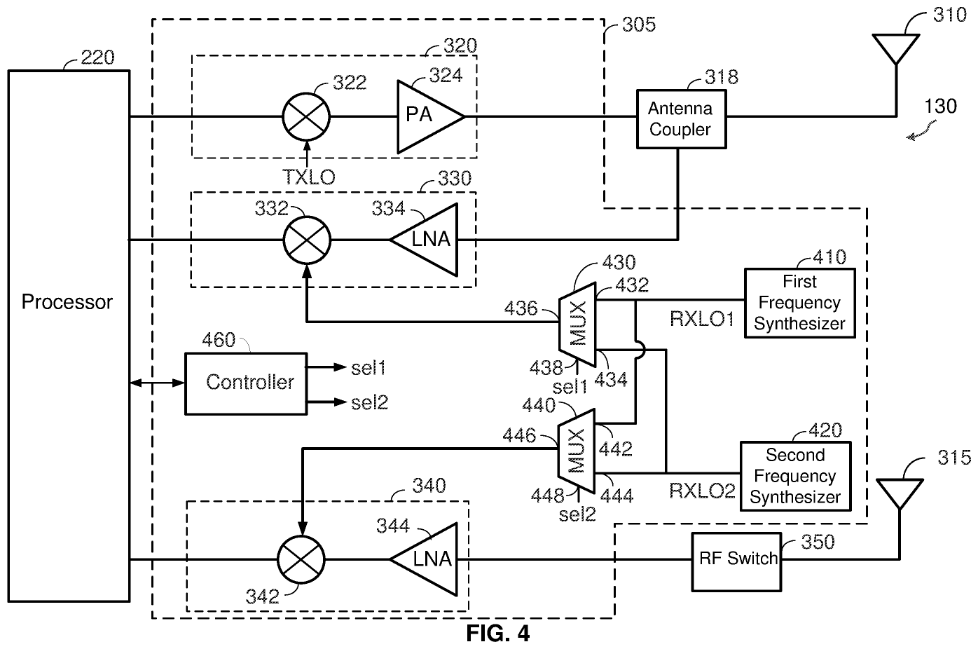

FIG. 4 shows an example in which the wireless device 130 includes circuitry for operating the diversity transceiver 305 in different configurations. As discussed further below, the configurations may include one or more configurations that provide antenna diversity (e.g., for the first subscriber), and one or more other configurations that allow the first subscriber and the second subscriber to share the diversity transceiver 305 (e.g., in the DSDS mode) to reduce area and cost.

In this example, the wireless device 130 includes a first frequency synthesizer 410 and a second frequency synthesizer 420. The first frequency synthesizer 410 is configured to generate a first receive local oscillator (RXLO1) signal for the first subscriber, and the second frequency synthesizer 420 is configured to generate a second receive local oscillator (RXLO2) signal for the second subscriber. The first frequency synthesizer 410 and the second frequency synthesizer 420 may each be implemented with a phase-locked loop (PLL), an inductor-capacitor (LC) oscillator, a ring oscillator, or the like. The RXLO1 signal may be used to frequency downconvert an RF signal for the first subscriber into a baseband or IF signal, and the RXLO2 signal may be used to frequency downconvert an RF signal for the second subscriber into a baseband or IF signal.

In certain aspects, the RF signal for the first subscriber and the RF signal for the second subscriber may have different frequencies. In these aspects, the RXLO1 signal and the RXLO2 have different frequencies to frequency downconvert the respective RF signal. In certain aspects, the RF signal for the first subscriber and the RF signal for the second subscriber may use different radio access technologies (RATs) or the same RAT.

In this example, the wireless device 130 includes a first multiplexer 430 and a second multiplexer 440. The first multiplexer 430 has a first input 432, a second input 434, and an output 436. The first input 432 is coupled to the first frequency synthesizer 410 to receive the RXLO1 signal, the second input 434 is coupled to the second frequency synthesizer 420 to receive the RXLO2 signal, and the output 436 is coupled to the first receive mixer 332. The first multiplexer 430 is configured to receive a first select signal (labeled “sel1”) at select input 438 and selectively couple the RXLO1 signal or the RXLO2 to the first receive mixer 332 based on the first select signal. For example, the first multiplexer 430 may select the RXLO1 signal when the first select signal has a first logic value and select the RXLO2 signal when the first select signal has a second logic value. The first logic value may be one and the second logic value may be zero, or vice versa.

The second multiplexer 440 has a first input 442, a second input 444, and an output 446. The first input 442 is coupled to the first frequency synthesizer 410 to receive the RXLO1 signal, the second input 444 is coupled to the second frequency synthesizer 420 to receive the RXLO2 signal, and the output 446 is coupled to the second receive mixer 342. The second multiplexer 440 is configured to receive a second select signal (labeled “sel2”) at select input 448 and selectively couple the RXLO1 signal or the RXLO2 to the second receive mixer 342 based on the second select signal. For example, the second multiplexer 440 may select the RXLO1 signal when the second select signal has the first logic value and select the RXLO2 signal when the second select signal has the second logic value, or vice versa.

In this example, the wireless device 130 includes a controller 460 for generating the first select signal and the second select signal. The individual connections between the controller 460 and the multiplexers 430 and 440 are not explicitly shown in FIG. 4 for ease of illustration. The controller 460 may configure the diversity transceiver 305 to operate in different configurations by controlling the selections of the multiplexers 430 and 440 using the first and second select signals. Exemplary configurations that may be supported by the controller 460 are discussed further below.

In a first configuration, the diversity transceiver 305 is configured to receive a first RF signal for the first subscriber using both receive circuits 330 and 340 for antenna diversity. In this configuration, the controller 460 causes the first multiplexer 430 and the second multiplexer 440 to both select the RXLO1 signal using the first and second select signals. Thus, the RXLO1 signal is output to both the first receive mixer 332 and the second receive mixer 342.

In the first configuration, the first antenna 310 receives a first copy of the first RF signal and the second antenna 315 receives a second copy of the first RF signal. The first RF signal may be transmitted from the first base station 110 (shown in FIG. 1). Because the first antenna 310 and the second antenna 315 are spaced apart and/or orientated in different directions, the first copy of the first RF signal and the second copy of the first RF signal may experience different levels of fading, interference, etc. In the first configuration, the wireless device 130 may also transmit an RF signal for the first subscriber via the first antenna 310 using the transmit circuit 320.

In the first configuration, the first receive circuit 330 (also referred to as the primary receive circuit) receives the first copy of the first RF signal via the antenna coupler 318.

The first low-noise amplifier 334 amplifies the first copy of the first RF signal, and the first receive mixer 332 mixes the first copy of the first RF signal with the RXLO1 signal to frequency downconvert the first copy of the first RF signal into a first baseband signal or first IF signal. For the example of the first IF signal, the first receive circuit 330 may include an additional mixer (not shown) to frequency downconvert the first IF signal into the first baseband signal.

The second receive circuit 340 (also referred to as the secondary or diversity receive circuit) receives the second copy of the first RF signal. The second low-noise amplifier 344 amplifies the second copy of the first RF signal, and the second receive mixer 342 mixes the second copy of the first RF signal with the RXLO1 signal to frequency downconvert the second copy of the first RF signal into a second baseband signal or second IF signal. For the example of the second IF signal, the second receive circuit 340 may include an additional mixer (not shown) to frequency downconvert the second IF signal into the second baseband signal.

The processor 220 receives the first baseband signal from the first receive circuit 330 and receives the second baseband signal from the second receive circuit 340. The processor 220 combines the first baseband signal and the second baseband signal into a combined signal to provide diversity gain (e.g., to increase signal-to-interference ratio). The processor 220 may employ one or more combining techniques known in the art to combine the first baseband signal and the second baseband signal including maximal ratio combining, minimum mean square error, equal-gain combining, active null steering, and/or another combining technique. The processor 220 may then process the combined signal to recover data and/or control information for the first subscriber.

It is to be appreciated that the controller 460 may also configure the diversity transceiver 305 to receive an RF signal for the second subscriber using antenna diversity. In this configuration, the controller 460 causes the first multiplexer 430 and the second multiplexer 440 to both select the RXLO2 signal using the first and second select signals. Thus, the RXLO2 signal is output to both the first receive mixer 332 and the second receive mixer 342. In this configuration, the first receive circuit 330 receives a first copy of the RF signal for the second subscriber via the first antenna 310, and the second receive circuit 340 receives a second copy of the RF signal for the second subscriber via the second antenna 315. The processor 220 may receive the corresponding baseband signals from the receive circuits 330 and 340, and combine the baseband signals using one or more combining techniques including maximal ratio combining, minimum mean square error, equal-gain combining, active null steering, and/or another combining technique.

In a second configuration, the diversity transceiver 305 is configured to receive a second RF signal for the first subscriber using the first receive circuit 330 and receive a third RF signal for the second subscriber using the second receive circuit 340. The second RF signal may have the same frequency as the first RF signal discussed above or a different frequency. In the second configuration, the controller 460 causes the first multiplexer 430 to select the RXLO1 signal and causes the second multiplexer 440 to select the RXLO2 signal using the first and second select signals. Thus, the RXLO1 signal is output to the first receive mixer 332 and the RXLO2 signal is output to the second receive mixer 342.

The second RF signal may be transmitted from the first base station 110 and the third RF signal may be transmitted from the second base station 120. However, it is to be appreciated that the present disclosure is not limited to this example. In another example, the second RF signal and the third RF signal may both be transmitted from the first base station 110. The first RF signal and the second RF signal may be transmitted using different frequencies and/or different RATs.

In the second configuration, the first antenna 310 receives the second RF signal for the first subscriber, and the second antenna 315 receives the third RF signal for the second subscriber. In the second configuration, the wireless device 130 may also transmit an RF signal for the first subscriber via the first antenna 310 using the transmit circuit 320. The second configuration may be operate the wireless device 130 in dual receive DSDS (DR-DSDS) mode, in which the wireless device 130 may transmit and receive RF signals (e.g., the second RF signal) for the first subscriber while receiving an RF signal (e.g., the third RF signal) for the second subscriber.

In the second configuration, the first receive circuit 330 receives the second RF signal for the first subscriber via the antenna coupler 318. The first low-noise amplifier 334 amplifies the second RF signal, and the first receive mixer 332 mixes the second RF signal with the RXLO1 signal to frequency downconvert the second RF signal into a third baseband signal or third IF signal. For the example of the third IF signal, the first receive circuit 330 may include an additional mixer (not shown) to frequency downconvert the third IF signal into the third baseband signal.

The second receive circuit 340 receives the third RF signal for the second subscriber via the second antenna 315. The second low-noise amplifier 344 amplifies the third RF signal, and the second receive mixer 342 mixes the third RF signal with the RXLO2 signal to frequency downconvert the third RF signal into a fourth baseband signal or fourth IF signal. For the example of the fourth IF signal, the second receive circuit 340 may include an additional mixer (not shown) to frequency downconvert the fourth IF signal into the fourth baseband signal.

The processor 220 receives the third baseband signal from the first receive circuit 330 and receives the fourth baseband signal from the second receive circuit 340. The processor 220 may process the third baseband signal to recover data and/or control information for the first subscriber and process the fourth baseband signal to recover data and/or control information for the second subscriber. Processing performed by the processor 220 may include demodulation, decoding etc.

In the second configuration, the wireless device 130 may transmit and receive RF signals (e.g., the second RF signal) for the first subscriber using the transmit circuit 320 and the first receive circuit 330 while receiving an RF signal (e.g., the third RF signal) for the second subscriber using the second receive circuit 340. In this example, the wireless device 130 may actively receive and/or transmit signals for the first subscriber (e.g., to support a voice call for the first subscriber and/or a data transfer for the first subscriber). Also, in this example, the wireless device 130 may receive a signal (e.g., the third RF signal) providing data and/or control information for the second subscriber. For example, the signal may include a paging message indicating that the second subscriber has a text message, an alert, and/or an incoming call. In this example, the processor 220 may determine the second subscriber has a text message, an alert, and/or an incoming call based on the paging message, and notify the user of the text message, alert, and/or the incoming call via the user interface 250 (shown in FIG. 2).

In a third configuration, the diversity transceiver 305 is configured to receive the second RF signal for the first subscriber using the second receive circuit 340 and receive the third RF signal for the second subscriber using the first receive circuit 330. The third configuration differs from the second configuration discussed above in that the second receive circuit 340 is used to receive the second RF signal for the first subscriber instead of the first receive circuit 330, and the first receive circuit 330 is used to receive the third RF signal for the second subscriber instead of the second receive circuit 330.

In the third configuration, the controller 460 causes the first multiplexer 430 to select the RXLO2 signal and causes the second multiplexer 440 to select the RXLO1 signal using the first and second select signals. Thus, the RXLO2 signal is output to the first receive mixer 332 and the RXLO1 signal is output to the second receive mixer 342.

In the third configuration, the first receive circuit 330 receives the third RF signal for the second subscriber from the first antenna 310 via the antenna coupler 318. The first low-noise amplifier 334 amplifies the third RF signal, and the first receive mixer 332 mixes the third RF signal with the RXLO2 signal to frequency downconvert the third RF signal into the fourth baseband signal or the fourth IF signal discussed above. For the example of the fourth IF signal, the first receive circuit 330 may include an additional mixer (not shown) to frequency downconvert the fourth IF signal into the fourth baseband signal.

The second receive circuit 340 receives the second RF signal for the first subscriber via the second antenna 315. The second low-noise amplifier 344 amplifies the second RF signal, and the second receive mixer 342 mixes the second RF signal with the RXLO1 signal to frequency downconvert the second RF signal into the third baseband signal or the third IF signal. For the example of the third IF signal, the second receive circuit 340 may include an additional mixer (not shown) to frequency downconvert the third IF signal into the third baseband signal. In this configuration, the second receive circuit 340 may be associated with the transmit circuit 320 in order to transmit an RF signal for the first subscriber via the first antenna 310 using the transmit circuit 320.

The processor 220 receives the fourth baseband signal from the first receive circuit 330 and receives the third baseband signal from the second receive circuit 340. The processor 220 may process the third baseband signal to recover data and/or control information for the first subscriber and process the fourth baseband signal to recover data and/or control information for the second subscriber, as discussed above. In this example, the controller 460 may indicate to the processor 220 that the third baseband signal is received from the second receive circuit 340 and the fourth baseband signal is received from the first receive circuit 330.

In a fourth configuration, the diversity transceiver 305 is configured to receive a fourth RF signal for the first subscriber using the first receive circuit 330. In this configuration, the second receive circuit 340 may be powered down to conserve power. The fourth RF signal may have the same frequency as the first RF signal discussed above or a different frequency. Thus, in the fourth configuration, an RF signal (e.g., fourth RF signal) is received for the first subscriber without the antenna diversity used in the first configuration. The fourth configuration may be used, for example, when the fourth RF signal has a high signal strength and antenna diversity is not needed to reliably receive the fourth RF signal. In the fourth configuration, the wireless device 130 may also transmit an RF signal for the first subscriber via the first antenna 310 using the transmit circuit 320.

In the fourth configuration, the controller 460 causes the first multiplexer 430 to select the RXLO1 signal using the first select signal. Thus, the RXLO1 signal is output to the first receive mixer 332.

In the fourth configuration, the first receive circuit 330 receives the fourth RF signal for the first subscriber from the first antenna 310 via the antenna coupler 318. The first low-noise amplifier 334 amplifies the fourth RF signal, and the first receive mixer 332 mixes the fourth RF signal with the RXLO1 signal to frequency downconvert the fourth RF signal into a fifth baseband signal or fifth IF signal. For the example of the fifth IF signal, the first receive circuit 330 may include an additional mixer (not shown) to frequency downconvert the fifth IF signal into the fifth baseband signal. The processor 220 receives the fifth baseband signal from the first receive circuit 330 and processes the fifth baseband signal to recover data and/or control information for the first subscriber.

In a fifth configuration, the diversity transceiver 305 is configured to receive the fourth RF signal for the first subscriber using the second receive circuit 340 instead of the first receive circuit 330. The fifth configuration may be used, for example, when the second antenna 315 is able to receive the fourth RF signal with higher signal strength than the first antenna 310 and/or another factor. In the fifth configuration, the controller 460 causes the second multiplexer 440 to select the RXLO1 signal using the second select signal. Thus, the RXLO1 signal is output to the second receive mixer 342.

In the fifth configuration, the second receive circuit 340 receives the fourth RF signal for the first subscriber via the second antenna 315. The second low-noise amplifier 344 amplifies the fourth RF signal, and the second receive mixer 342 mixes the fourth RF signal with the RXLO1 signal to frequency downconvert the fourth RF signal into the fifth baseband signal or the fifth IF signal discussed above. For the example of the fifth IF signal, the second receive circuit 340 may include an additional mixer (not shown) to frequency downconvert the fifth IF signal into the fifth baseband signal. The processor 220 receives the fifth baseband signal from the second receive circuit 340 and processes the fifth baseband signal to recover data and/or control information for the first subscriber. In this example, the controller 460 may indicate to the processor 220 that the fifth baseband signal is received from the second receive circuit 340 instead of the first receive circuit 330.

Thus, in the example shown in FIG. 4, the wireless device 130 may support at least the five configurations discussed above for the diversity transceiver 305. In the first configuration, the RXLO1 signal is output to both receive mixers 332 and 342. In the second configuration, the RXLO1 signal is output to the first receive mixer 332 and the RXLO2 signal is output to the second receive mixer 342. In the third configuration, the RXLO2 signal is output to the first receive mixer 332 and the RXLO1 signal is output to the second receive mixer 342. In the fourth configuration, the RXLO1 signal is output to the first receive mixer 332. In the fifth configuration, the RXLO1 signal is output to the second receive mixer 342. As discussed above, the wireless device 130 may also support a configuration that provides antenna diversity for the second subscriber in which the RXLO2 signal is output to both receive mixers 332 and 342.

It is to be appreciated that the wireless device 130 may support all of the exemplary configurations discussed above or a subset of the exemplary configurations. In some implementations, the first multiplexer 430 may be omitted with the first frequency synthesizer 410 coupled to the first receive mixer 332 without the multiplexer 430. In these implementations, the wireless device 130 may support at least the first configuration and the second configuration since the first frequency synthesizer 410 outputs the RXLO1 signal to the first receive mixer 332 in both of these configurations. In these implementations, the controller 460 causes the second multiplexer 440 to select the RXLO1 signal in the first configuration and causes the second multiplexer 440 to select the RXLO2 signal in the second configuration, as discussed above.

It is to be appreciated that first antenna 310 and the second antenna 315 may be shared among multiple transceivers that include the diversity transceiver 305. For example, the first antenna 310 may be coupled to the multiple transceivers through a diplexer or a triplexer (not shown) located between the antenna coupler 318 and the first antenna 310. In this example, the multiple transceivers may operate in different frequency bands, and the diplexer or triplexer may separate and/or combine RF signals in the different frequency bands to allow the multiple transceivers to share the first antenna 310. Thus, the antenna coupler 318 may be coupled to the first antenna 310 through a diplexer or a triplexer. The second antenna 315 may be coupled to the multiple transceivers in a similar manner using a diplexer or a triplexer (e.g., to support multiple frequency bands).

In a further aspect in an example implementation, a gating circuit may be provided between the multiplexers 430 and 440 and the frequency synthesizer 410 and 420 to improve isolation between the RXLO1 signal and the RXLO2 signal, as discussed further below. This may allow for further isolation between the RXLO1 signal and the RXLO2 signals when one of the RXLO1 signal and the RXLO2 signal is selected based on the first select signal (e.g., where isolation may help in configurations where there may be some coupling between the RXLO1 signal and the RXLO2 which can degrade the performance of the first receive circuit 330).

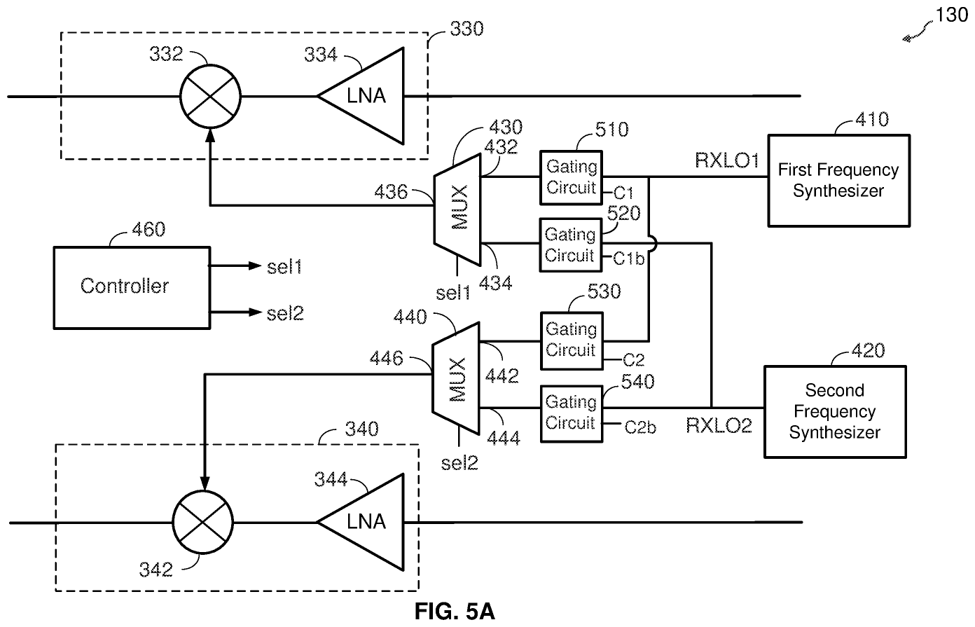

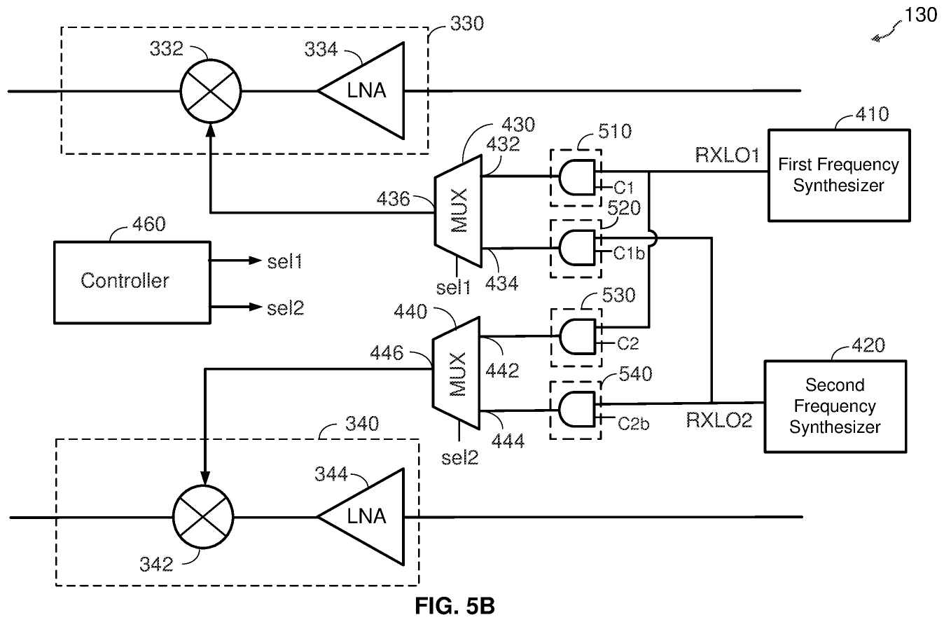

FIG. 5A shows an example in which the wireless device 130 includes a first gating circuit 510 and a second gating circuit 520. The first gating circuit 510 is coupled between the first input 432 of the first multiplexer 430 and the first frequency synthesizer 410, and the second gating circuit 520 is coupled between the second input 434 of the first multiplexer 430 and the second frequency synthesizer 420. In this example, the first gating circuit 510 is configured to selectively gate the RXLO1 signal from the first frequency synthesizer 410 based on a first control signal C1, and the second gating circuit 520 is configured to selectively gate the RXLO2 signal from the second frequency synthesizer 420 based on the complement of the first control signal C1 (labeled “C1b” in FIG. 5A).

In this example, the first gating circuit 510 and the second gating circuit 520 may be configured such that one of the first gating circuit 510 and the second gating circuit 520 passes one of the RXLO1 signal and the RXLO2 signal to the first multiplexer 430 at a time based on the first control signal C1. For example, the first gating circuit 510 may pass the RXLO1 signal to the first multiplexer 430 and the second gating circuit 520 may gate the RXLO2 signal when the first control signal C1 has a first logic value. The first gating circuit 510 may gate the RXLO1 signal and the second gating circuit 520 may pass the RXLO2 signal to the first multiplexer 430 when the first control signal C1 has a second logic value. The first logic value may be one and the second logic value may be zero, or vice versa.

The first control signal C1 may be generated by the controller 460. In some implementations, the first control signal C1 may be the same as the first select signal. In these implementations, the first gating circuit 510 may be configured to pass the RXLO1 signal and the second gating circuit 520 may be configured to gate the RXLO2 signal when the first select signal causes the first multiplexer 430 to select the RXLO1 signal. Also, the first gating circuit 510 may be configured to gate the RXLO1 signal and the second gating circuit 520 may be configured to pass the RXLO2 signal when the first select signal causes the first multiplexer 430 to select the RXLO2 signal.

In this example, the controller 460 causes the first gating circuit 510 to pass the RXLO1 signal and the second gating circuit 520 to gate the RXLO2 signal in the first configuration, the second configuration, and the fourth configuration using the first control signal C1 (which may be the same as the first select signal). The controller 460 causes the first gating circuit 510 to gate the RXLO1 signal and the second gating circuit 520 to pass the RXLO2 signal in the third configuration.

Thus, in this example, only one of the RXLO1 signal and the RXLO2 signal is input to the first multiplexer 430 at a time. This significantly reduces coupling between the RXLO1 signal and the RXLO2 signal in the first multiplexer 430, improving isolation between the RXLO1 signal and the RXLO2 signal.

In the example in FIG. 5A, the wireless device 130 also includes a third gating circuit 530 and a fourth gating circuit 540. The third gating circuit 530 is coupled between the first input 442 of the second multiplexer 440 and the first frequency synthesizer 410, and the fourth gating circuit 540 is coupled between the second input 444 of the second multiplexer 440 and the second frequency synthesizer 420. In this example, the third gating circuit 530 is configured to selectively gate the RXLO1 signal from the first frequency synthesizer 410 based on a second control signal C2, and the fourth gating circuit 540 is configured to selectively gate the RXLO2 signal from the second frequency synthesizer 420 based on the complement of the second control signal C2 (labeled “C2b” in FIG. 5A).

In this example, the third gating circuit 530 and the fourth gating circuit 540 may be configured such that one of the third gating circuit 530 and the fourth gating circuit 540 passes one of the RXLO1 signal and the RXLO2 signal to the second multiplexer 440 at a time based on the second control signal C2. For example, the third gating circuit 530 may pass the RXLO1 signal to the second multiplexer 440 and the fourth gating circuit 540 may gate the RXLO2 signal when the second control signal C2 has the first logic value. The third gating circuit 530 may gate the RXLO1 signal and the fourth gating circuit 540 may pass the RXLO2 signal to the second multiplexer 440 when the second control signal C2 has the second logic value.

The second control signal C2 may be generated by the controller 460. In some implementations, the second control signal C2 may be the same as the second select signal. In these implementations, the third gating circuit 530 may be configured to pass the RXLO1 signal and the fourth gating circuit 540 may be configured to gate the RXLO2 signal when the second select signal causes the second multiplexer 440 to select the RXLO1 signal. Also, the third gating circuit 530 may be configured to gate the RXLO1 signal and the fourth gating circuit 540 may be configured to pass the RXLO2 signal when the second select signal causes the second multiplexer 440 to select the RXLO2 signal.

In this example, the controller 460 causes the third gating circuit 530 to pass the RXLO1 signal and the fourth gating circuit 540 to gate the RXLO2 signal in the first configuration, the third configuration, and the fifth configuration using the second control signal C2 (which may be the same as the first select signal). The controller 460 causes the third gating circuit 530 to gate the RXLO1 signal and the fourth gating circuit 540 to pass the RXLO2 signal in the second configuration.

Thus, in this example, only one of the RXLO1 signal and the RXLO2 signal is input to the second multiplexer 440 at a time. This significantly reduces coupling between the RXLO1 signal and the RXLO2 signal in the second multiplexer 440, improving isolation between the RXLO1 signal and the RXLO2 signal.

Each of the gating circuits 510, 520, 530, and 540 may be implemented with a logic gate including an AND gate, a NAND gate, or another type of logic gate. FIG. 5B shows an example in which each of the gating circuits 510, 520, 530, and 540 is implemented with a respective AND gate. An AND gate may be implemented using two NAND gates, a NAND gate and an inverter, or the like.

In the example in FIG. 5B, the first gating circuit 510 gates the RXLO1 signal when the first control signal C1 is zero and passes the RXLO1 signal when the first control signal C1 is one. The second gating circuit 520 gates the RXLO2 signal when the first control signal C1 is one (i.e., the complementary signal C1b is zero) and passes the RXLO2 signal when the first control signal C1 is zero (i.e., the complementary signal C1b is one). The third gating circuit 530 gates the RXLO1 signal when the second control signal C2 is zero and passes the RXLO1 signal when the second control signal C2 is one. The fourth gating circuit 540 gates the RXLO2 signal when the second control signal C2 is one (i.e., the complementary signal C2b is zero) and passes the RXLO2 signal when the second control signal C2 is zero (i.e., the complementary signal C2b is one).

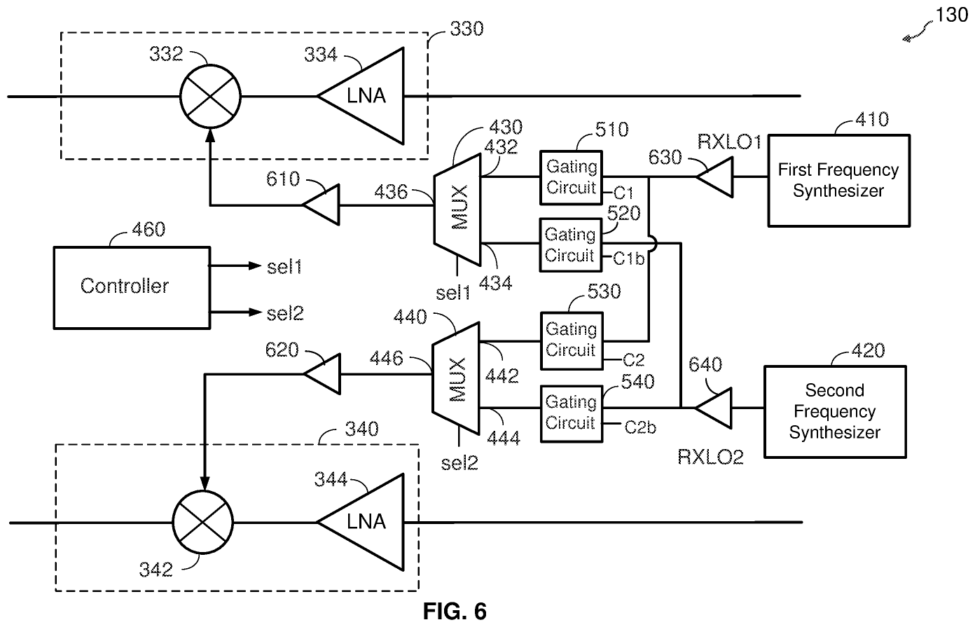

The wireless device 130 may include one or more drivers between the frequency synthesizers 410 and 420 and the mixers 332 and 342. In this regard, FIG. 6 shows an example in which the wireless device 130 includes a first driver 610 coupled between the output 436 of the first multiplexer 430 and the first receive mixer 332, and a second driver 620 coupled between the output 446 of the second multiplexer 440 and the second receive mixer 342. In this example, the first driver 610 helps drive the first receive mixer 332 with the RXLO1 signal or the RXLO2 signal output from the first multiplexer 430, and the second driver 620 helps drive the second receive mixer 342 with the RXLO1 signal or the RXLO2 signal output from the second multiplexer 440. In this example, the output 436 of the first multiplexer 430 is coupled to the first receive mixer 332 through the first driver 610, and the output 446 of the second multiplexer 440 is coupled to the second receive mixer 342 through the second driver 620.

In the example in FIG. 6, the wireless device 130 also includes a third driver 630 coupled between the first frequency synthesizer 410 and the multiplexers 430 and 440, and a fourth driver 640 coupled between the second frequency synthesizer 420 and the multiplexer 430 and 440. In this example, the third driver 630 helps drive the inputs of the multiplexers 430 and 440 with the RXLO1 signal from the first frequency synthesizer 410, and the fourth driver 640 helps drive the inputs of the multiplexers 430 and 440 with the RXLO2 signal from the second frequency synthesizer 420.

It is to be appreciated that one or more of the drivers 610, 620, 630, and 640 may be omitted in some implementations. The drivers 610, 620, 630, and 640 may also be referred to as LO drivers, LO amplifiers, or another term.

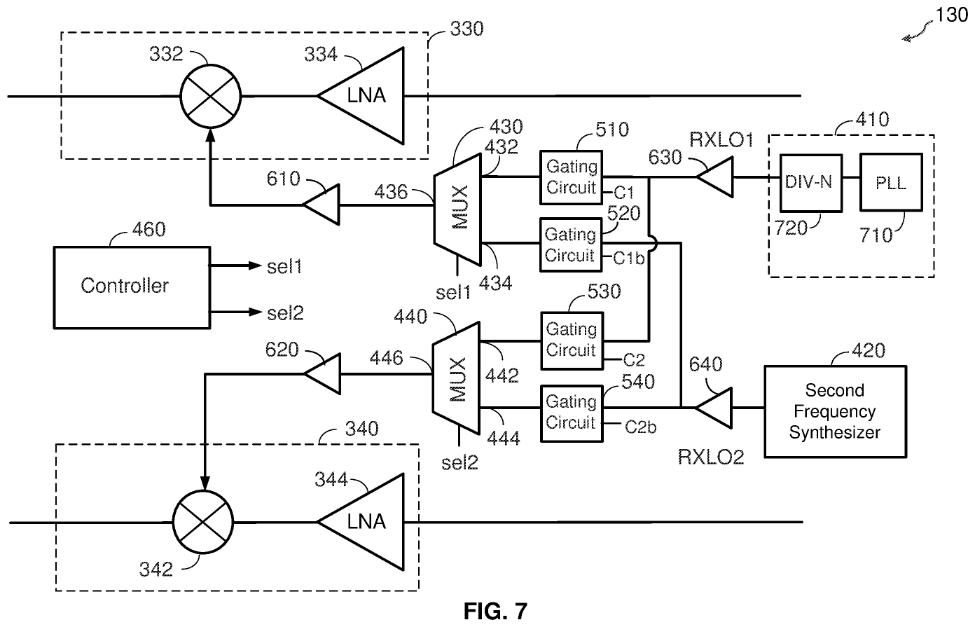

The first frequency synthesizer 410 and the second frequency synthesizer 420 may each be implemented with a phase-locked loop (PLL), an inductor-capacitor (LC) oscillator, a ring oscillator, or the like. In some implementations, the frequency synthesizer 410 may include a frequency divider in combination with a PLL. In this regard, FIG. 7 shows an example in which first frequency synthesizer 410 includes a PLL 710 and a frequency divider 720 coupled to the output of the PLL 710 according to certain aspects. In this example, the frequency divider 720 is configured to divide the frequency of the PLL 710 to generate the RXLO1. For example, the frequency divider 720 may divide the frequency of the PLL 710 by an adjustable divider to adjust the frequency of the RXLO1 signal. In this example, the second frequency synthesizer 420 may be implemented with a PLL, a combination of a PLL and a frequency divider, a ring oscillator, an LC oscillator, or the like.

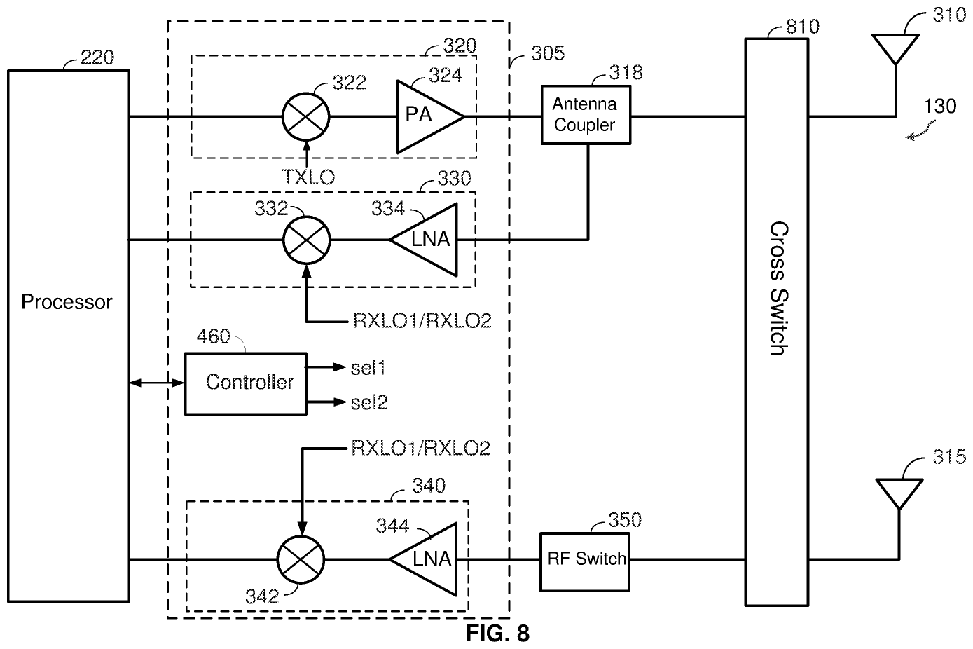

FIG. 8 shows an example in which the wireless device 130 includes a cross switch 810 to support antenna switched diversity (ASDiv). The cross switch 810 is configured to selectively couple the antenna coupler 318 to the first antenna 310 or the second antenna 315 under the control of the controller 460. The cross switch 810 may also be configured to selectively couple the second receive circuit 340 to the first antenna 310 or the second antenna 315 under the control of the controller 460. In this example, the cross switch 810 allows the antennas 310 and 315 to exchange their roles and opportunistically improve the transmit power of a transmit RF signal and improve the signal-to-noise (SNR) of a received RF signal. For example, in some cases, the first antenna 310 may be blocked by a user's hand or another obstruction. In these cases, the controller 460 may switch the transmit circuit 320 and the first receive circuit 330 to the second antenna 315 by causing the cross switch 810 to couple the antenna coupler 318 to the second antenna 315. As a result, a transmit RF signal from the transmit circuit 320 is routed to the second antenna 315 through the cross switch 810, and a receive RF received by the second antenna 315 is routed to the first receive circuit 330 through the cross switch 810. Similarly, the controller 460 may cause the cross switch 810 to couple the first antenna 310 to the second receive circuit 340 to route an RF signal received by the first antenna 310 to the second receive circuit 340 through the cross switch 810.

The wireless device 130 in the example in FIG. 8 may include the multiplexers 430 and 440 (shown in FIGS. 4, 5A, 5B, 6, and 7) to switch each of the mixers 332 and 342 between the RXLO1 signal and the RXLO2 signal (e.g., to support the exemplary configurations discussed above).

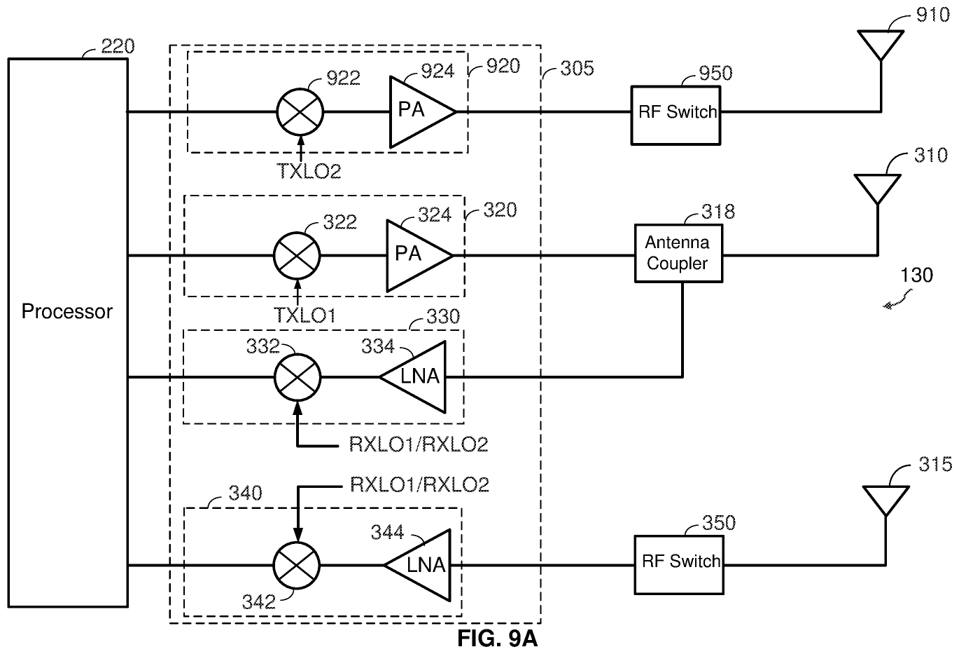

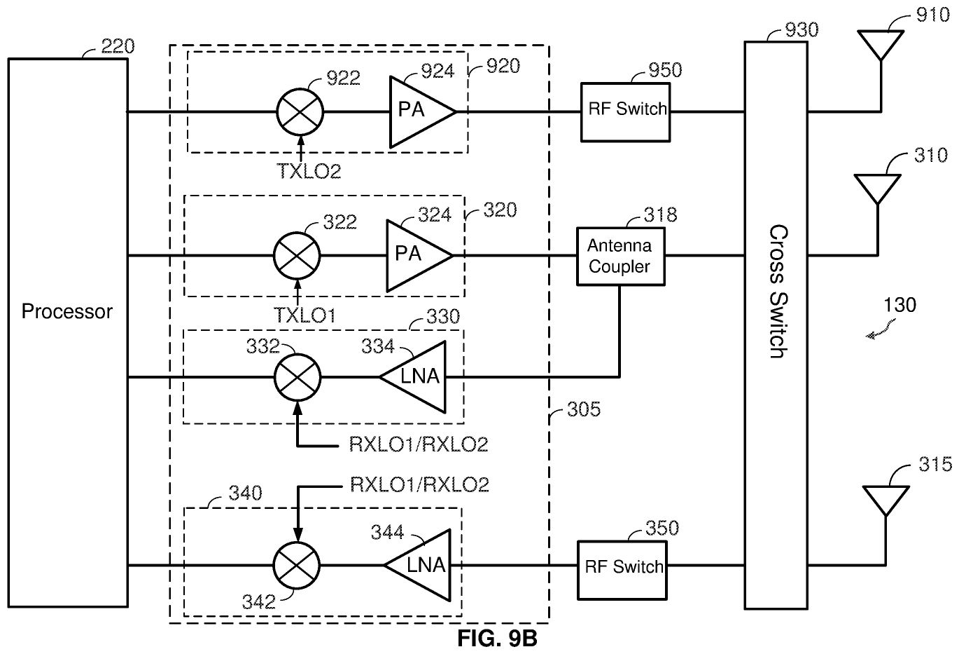

FIG. 9A shows an example in which the wireless device 130 includes a second transmit circuit 920 and a third antenna 910 according to certain aspects. The second transmit circuit 920 includes a second transmit mixer 922 and a second power amplifier 924. The second transmit mixer 922 is coupled between the processor 220 and the input of the second power amplifier 924, and the output of the power amplifier 924 is coupled to the third antenna 910. For example, the second transmit circuit 920 may be coupled to the third antenna 910 through an RF switch 950 which allows the third antenna 910 to be selectively coupled to the second transmit circuit 920. The RF switch 950 may also allow the third antenna 910 to be selectively coupled to one or more other receive circuits and/or transmitters (not shown).

It is to be appreciated that the second transmit circuit 920 may include one or more additional components (not shown) in the transmit path. In the discussion below, the transmit circuit 320 is referred to as the first transmit circuit, the transmit mixer 322 is referred to as the first transmit mixer, and the power amplifier 324 is referred to as the first power amplifier.

In one example, the first transmit mixer 322 may be configured to mix a baseband signal or an IF signal for the first subscriber with a first transmit local oscillator (TXLO1) signal to frequency upconvert the baseband signal or the IF signal into an RF signal for the first subscriber. The first power amplifier 324 may then amplify the RF signal (e.g., for transmission via the first antenna 310). Also, in this example, the second the second transmit mixer 922 may be configured to mix a baseband signal or an IF signal for the second subscriber with a second transmit local oscillator (TXLO2) signal to frequency upconvert the baseband signal or the IF signal into an RF frequency signal for the second subscriber. The second power amplifier 924 may then amplify the RF signal (e.g., for transmission via the third antenna 910). It is to be appreciated that the first transmit circuit 320 and the second transmit circuit 920 are not limited to this example.

In this example, the wireless device 130 may support one or more of the exemplary configurations discussed above with reference to FIGS. 4, 5A, 5B, 6, and 7. The wireless device 130 may also support a configuration for a dual SIM dual active (DSDA) mode, in which both the first subscriber and the second subscriber may actively receive and transmit signals at the same time. In this configuration, the first transmit circuit 320 transmits a transmit RF signal for the first subscriber via the first antenna 310 and the first receive circuit 330 receives a receive RF signal for the first subscriber via the first antenna 310. The first multiplexer 430 (shown in FIGS. 4, 5A, 5B, 6, and 7) may output the RXLO1 signal to the first receive mixer 332 in this configuration. The first transmit circuit 320 and the first receive circuit 330 are coupled to the first antenna 310 through the antenna coupler 318, which may include a switch or a duplexer to help isolate the transmit RF signal and the receive RF signal for the first subscriber.

Also, in this configuration, the second transmit circuit 920 transmits a transmit RF signal for the second subscriber via the third antenna 910 and the second receive circuit 340 receives a receive RF signal for the second subscriber via the second antenna 315. The second multiplexer 440 (shown in FIGS. 4, 5A, 5B, 6, and 7) may output the RXLO2 signal to the second receive mixer 342 in this configuration. In the example in FIG. 9A, the transmit RF signal for the second subscriber and the receive RF signal for the second subscriber use different antennas (i.e., the third antenna 910 and the second antenna 315), and are therefore isolated through the different antennas. In this example, the second receive circuit 340 may include a filter (not shown) in the receive path for rejecting antenna-coupled transmit RF signals.

FIG. 9B shows an example of a cross switch 930 added in the front end to support antenna switched diversity (ASDiv). For example, the cross switch 930 may be configured to selectively couple the antenna coupler 318 to the first antenna 310, the second antenna 315, or the third antenna 910. This allows the first transmit circuit 320 and the first receive circuit 330 to transmit and receive RF signals (e.g., for the first subscriber) using any one of the antennas 310, 315, and 910. The cross switch 930 may also be configured to swap the antennas 910 and 315 for the second receive circuit 340 and the second transmit circuit 920 such that the second transmit circuit 920 transmits a transmit RF signal via the second antenna 315, and the second receive circuit 340 receives a receive RF signal via the third antenna 910.

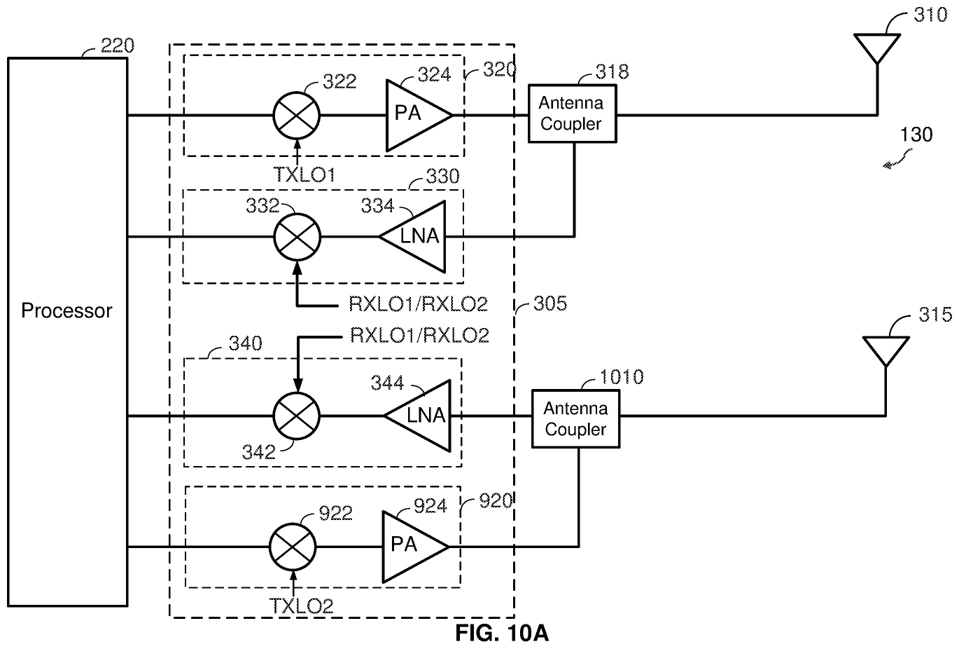

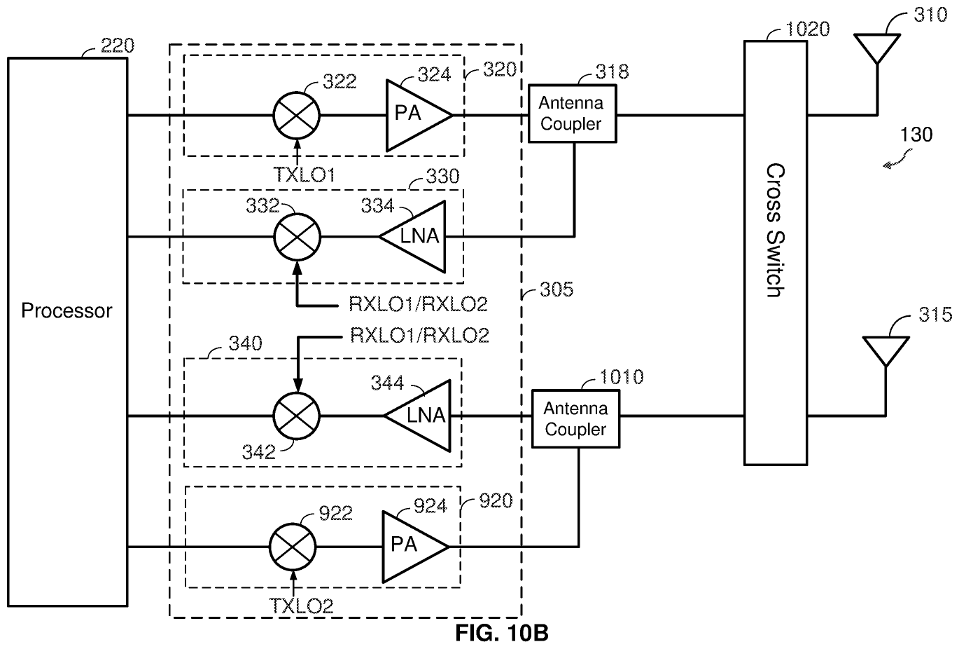

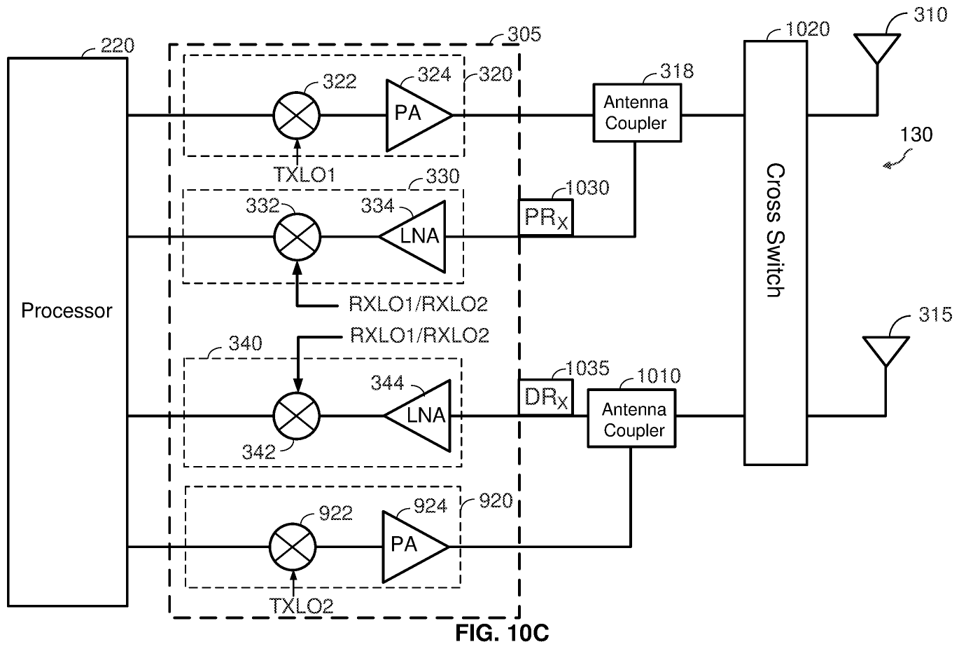

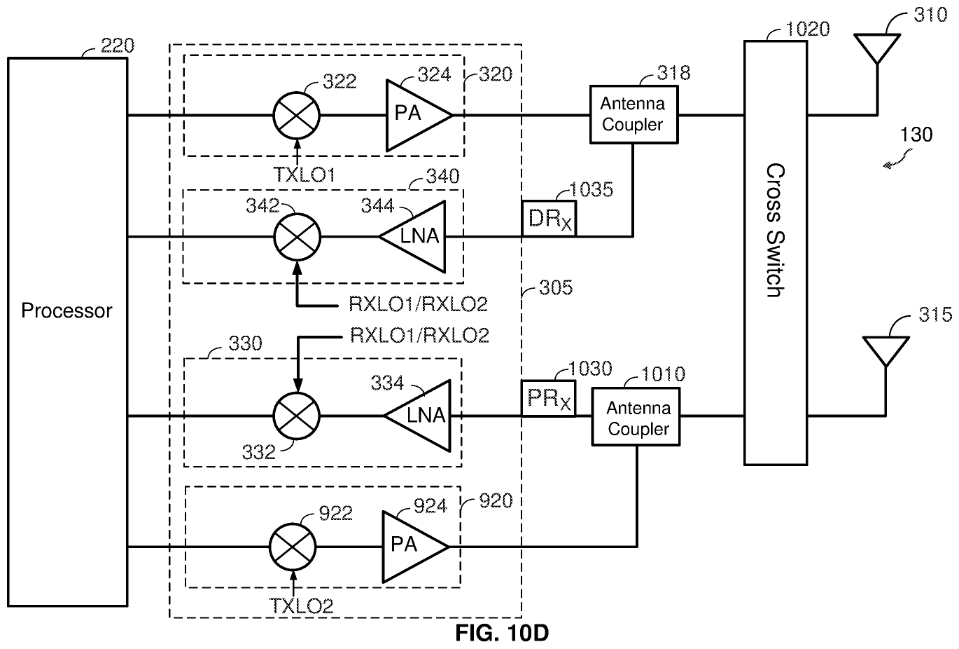

FIG. 10A shows an example in which wireless device 130 includes a second antenna coupler 1010, and the second transmit circuit 920 and the second receive circuit 340 are coupled to the second antenna 315 through the second antenna coupler 1010. The second antenna coupler 1010 may include a switch, a duplexer, or the like.

In this example, the wireless device 130 may support one or more of the exemplary configurations discussed above with reference to FIGS. 4, 5A, 5B, 6, and 7. The wireless device 130 may also support a configuration for the DSDA mode, in which both the first subscriber and the second subscriber may actively receive and transmit signals at the same time. In this configuration, the first transmit circuit 320 transmits a transmit RF signal for the first subscriber via the first antenna 310 and the first receive circuit 330 receives a receive RF signal for the first subscriber via the first antenna 310. The first multiplexer 430 (shown in FIGS. 4, 5A, 5B, 6, and 7) may output the RXLO1 signal to the first receive mixer 332 in this configuration. The first transmit circuit 320 and the first receive circuit 330 are coupled to the first antenna 310 through the antenna coupler 318, which may include a switch or a duplexer to help isolate the transmit RF signal and the receive RF signal for the first subscriber.

Also, in this configuration, the second transmit circuit 920 transmits a transmit RF signal for the second subscriber via the second antenna 315 and the second receive circuit 340 receives a receive RF signal for the second subscriber via the second antenna 315. The second multiplexer 440 (shown in FIGS. 4, 5A, 5B, 6, and 7) may output the RXLO2 signal to the second receive mixer 342 in this configuration. The second transmit circuit 920 and the second receive circuit 340 are coupled to the second antenna 315 through the antenna coupler 1010, which may include a switch or a duplexer to help isolate the transmit RF signal and the receive RF signal for the second subscriber.

FIG. 10B shows an example of a cross switch 1020 added in the front end to support antenna switched diversity (ASDiv). For example, the cross switch 1020 may be configured to selectively couple the antenna coupler 318 to the first antenna 310 or the second antenna 315, and selectively couple the antenna coupler 1010 to the second antenna 315 and the first antenna 310. Thia allows the first transmit circuit 320 and the first receive circuit 330 to swap antennas with the second transmit circuit 920 and the second receive circuit 340.

FIG. 10C shows an example in which the transceiver 305 includes a primary receive port 1030 and a diversity receive port 1035. In this example, the primary receive port 1030 and the diversity receive port 1035 are RF ports located at the boundary of the transceiver 305 (e.g., radio frequency integrated circuit (RFIC)) that allow front-end components such as duplexers, switches, or the like (e.g., part of the coupler block) to be coupled to the transceiver 305 based on PCB/architecture constraints. In the example in FIG. 10C, the first receive circuit 330 is coupled to the primary receive port 1030 of the transceiver 305, and the second receive circuit 340 is coupled to the diversity receive port 1035 of the transceiver 305.

FIG. 10D shows another example in which the antenna coupler 318 is routed to the diversity receive port 1035 to couple the first transmit circuit 320 and the second receive circuit 340 to the first antenna 310. FIG. 10D also shows an example in which the antenna coupler 1010 is routed to the primary receive port 1030 to couple the second transmit circuit 920 and the first receive circuit 330 to the second antenna 315.

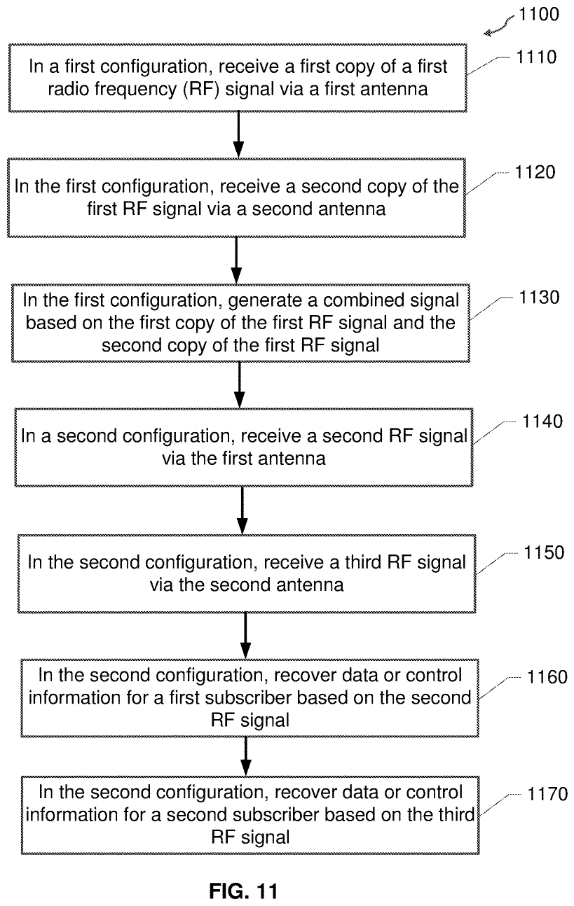

FIG. 11 shows an exemplary method 1100 of operating a wireless device (e.g., wireless device 130) according to certain aspects.

At block 1110, in a first configuration, a first copy of a first radio frequency (RF) signal is received via a first antenna. The first antenna may correspond to the first antenna 310.

At block 1120, in the first configuration, a second copy of the first RF signal is received via a second antenna. The second antenna may correspond to the second antenna 315.

At block 1130, in the first configuration, a combined signal is generated based on the first copy of the first RF signal and the second copy of the first RF signal. The combining may be performed by the processor 220. The combined signal may be processed by the processor 220 to recover data and/or control information for the first subscriber.

At block 1140, in a second configuration, a second RF signal is received via the first antenna.

At block 1150, in the second configuration, a third RF signal is received via the second antenna.

At block 1160, in the second configuration, data or control information is recovered for a first subscriber based on the second RF signal. For example, the data or control information may be recovered by the processor 220.

At block 1170, in the second configuration, data or control information is recovered for a second subscriber based on the third RF signal. For example, the data or control information may be recovered by the processor 220.

In certain aspects, the first subscriber is associated with a first subscriber identity module (SIM) (e.g., first SIM 255) and the second subscriber is associated with a second SIM (e.g., second SIM 260).

In certain aspects, the second RF signal is transmitted from a first base station (e.g., the first base station 110), and the third RF signal is transmitted from a second base station (e.g., the second base station 120).

In certain aspects, the method 1100 also includes converting the first copy of the first RF signal into a first baseband signal, and converting the second copy of the first RF signal into a second baseband signal, wherein generating the combined signal comprises combining the first baseband signal and the second baseband signal. For example, the first receive circuit 330 may convert the first copy of the first RF signal into the first baseband signal and the second receive circuit 340 may convert the second copy of the first RF signal into the second baseband signal.

In certain aspects, combining the first baseband signal and the second baseband signal comprises combining the first baseband signal and the second baseband signal using maximal ratio combining, minimum mean square error, equal-gain combining, active null steering, and/or another combining technique.

In certain aspects, converting the first copy of the first RF signal into the first baseband signal comprises mixing the first copy of the first RF signal with a first local oscillator (LO) signal (e.g., RXLO1) using a first mixer, and converting the second copy of the first RF signal into the second baseband signal comprises mixing the second copy of the first RF signal with the first LO signal using a second mixer. The first mixer may correspond to the first receive mixer 332 and the second mixer may correspond to the second receive mixer 342.

In certain aspects, the method 1100 further includes converting the second RF signal into a third baseband signal, and converting the third RF signal into a fourth baseband signal. For example, the first receive circuit 330 may convert the second RF signal into the third baseband signal, and the second receive circuit 340 may convert the third RF signal into the fourth baseband signal.

In certain aspects, recovering the data or the control information for the first subscriber comprises recovering the data or the control information for the first subscriber based on the third baseband signal, and recovering the data or the control information for the second subscriber comprises recovering the data or the control information for the second subscriber based on the fourth baseband signal. For example, the processor 220 may recover the data or control information for the first subscriber, and recover the data or control information for the second subscriber.

In certain aspects, converting the first copy of the first RF signal into the first baseband signal comprises mixing the first copy of the first RF signal with a first local oscillator (LO) signal (e.g., RXLO1) using a first mixer, converting the second copy of the first RF signal into the second baseband signal comprises mixing the second copy of the first RF signal with the first LO signal using a second mixer, converting the second RF signal into the third baseband signal comprises mixing the second RF signal with the first LO signal using the first mixer, and converting the third RF signal into the fourth baseband signal comprises mixing the third RF signal with a second LO signal (e.g., RXLO2) using the second mixer. For example, the multiplexers 430 and 440 may output the first LO signal (e.g., RXLO1 signal) to the first mixer and the second mixer in the first configuration, and output the first LO signal to the first mixer and output the second LO signal (e.g., RXLO2) to the second mixer in the second configuration.

Implementation examples are described in the following numbered clauses:
1. A system for wireless communications, comprising:
   a first receive circuit coupled to a first antenna, the first receive circuit comprising:
      a first low-noise amplifier coupled to the first antenna; and
      a first mixer coupled to the first low-noise amplifier;
   a second receive circuit coupled to a second antenna, the second receive circuit comprising:
      a second low-noise amplifier coupled to the second antenna; and
      a second mixer coupled to the second low-noise amplifier;
   a first frequency synthesizer configured to generate a first local oscillator (LO) signal;
   a second frequency synthesizer configured to generate a second LO signal;
   a first multiplexer configured to selectively couple the first LO signal or the second LO signal to the first mixer; and
   a second multiplexer configured to selectively couple the first LO signal or the second LO signal to the second mixer.
2. The system of clause 1, further comprising a controller configured to:
   in a first configuration, cause the first multiplexer to select the first LO signal and cause the second multiplexer to select the first LO; and
   in a second configuration, cause the first multiplexer to select the first LO signal and cause the second multiplexer to select the second LO signal.
3. The system of clause 2, further comprising a processor coupled to the first receive circuit and the second receive circuit, wherein the processor is configured to:
   in the first configuration,
      receive a first baseband signal from the first receive circuit and receive a second baseband signal from the second receive circuit; and
      combine the first baseband signal and the second baseband signal into a combined signal.
4. The system of clause 3, wherein the processor is configured to combine the first baseband signal and the second baseband signal using one or more of maximal ratio combining, minimum mean square error, equal-gain combining, and active null steering.
5. The system of clause 3 or 4, wherein the processor is further configured to:
   in the second configuration,
      receive a third baseband signal from the first receive circuit and receive a fourth baseband signal from the second receive circuit;
      recover data or control information for a first subscriber based on the third baseband signal; and
      recover data or control information for a second subscriber based on the fourth baseband signal.
6. The system of clause 5, wherein the first subscriber is associated with a first subscriber identity module (SIM) and the second subscriber is associated with a second SIM.
7. The system of any one of clauses 2 to 6, further comprising:
   a first gating circuit coupled between the first frequency synthesizer and a first input of the first multiplexer;
   a second gating circuit coupled between the second frequency synthesizer and a second input of the first multiplexer;
   a third gating circuit coupled between the first frequency synthesizer and a first input of the second multiplexer; and
   a fourth gating circuit coupled between the second frequency synthesizer and a second input of the second multiplexer.
8. The system of clause 7, wherein the controller is configured to:
   in the first configuration, cause the first gating circuit to pass the first LO signal to the first input of the first multiplexer, cause the second gating circuit to gate the second LO signal, cause the third gating circuit to pass the first LO signal to the first input of the second multiplexer, and cause the fourth gating circuit to gate the second LO signal; and
   in the second configuration, cause the first gating circuit to pass the first LO signal to the first input of the first multiplexer, cause the second gating circuit to gate the second LO signal, cause the third gating circuit to gate the first LO signal, and cause the fourth gating circuit to pass the second LO signal to the second input of the second multiplexer.
9. The system of clause 7 or 8, wherein each of the first gating circuit, the second gating circuit, the third gating circuit, and the fourth gating circuit comprises a respective AND gate.
10. The system of any one of clauses 1 to 9, further comprising:
   a first transmit circuit coupled to the first antenna, the first transmit circuit comprising:
      a first power amplifier coupled to the first antenna; and
      a third mixer coupled to the first power amplifier;
   a second transmit circuit coupled to a third antenna, the second transmit circuit comprising:
      a second power amplifier coupled to the third antenna; and
      a fourth mixer coupled to the second power amplifier.
11. The system of clause 10, further comprising an antenna coupler coupling the first transmit circuit and the first receive circuit to the first antenna.
12. The system of clause 10 or 11, further comprising a radio frequency (RF) switch configured to selectively couple the second transmit circuit to the third antenna.
13. The system of any one of clauses 10 to 12, further comprising a radio frequency (RF) switch configured to selectively couple the second receive circuit to the second antenna.
14. The system of any one of clauses 10 to 13, further comprising a controller configured to:
   in a first configuration, cause the first multiplexer to select the first LO signal and cause the second multiplexer to select the first LO, or cause the first multiplexer to select the second LO signal and the second multiplexer to select the second LO signal; and
   in a second configuration, cause the first multiplexer to select the first LO signal and cause the second multiplexer to select the second LO signal.
15. The system of clause 14, wherein:
   in the first configuration, the first receive circuit is configured to receive a first copy of a first receive radio frequency (RF) signal via the first antenna; and
   in the first configuration, the second receive circuit is configured to receive a second copy of the first receive RF signal via the second antenna.
16. The system of clause 15, wherein:
   in the second configuration, the first transmit circuit is configured to transmit a first transmit RF signal for a first subscriber via the first antenna;
   in the second configuration, the first receive circuit is configured to receive a second receive RF signal for the first subscriber via the first antenna;
   in the second configuration, the second transmit circuit is configured to transmit a second transmit RF signal for a second subscriber via the third antenna; and
   in the second configuration, the second receive circuit is configured to receive a third receive RF signal for the second subscriber via the second antenna.
17. The system of clause 16, wherein the first subscriber is associated with a first subscriber identity module (SIM) and the second subscriber is associated with a second SIM.
18. The system of any one of clauses 1 to 9, further comprising:
   a first transmit circuit coupled to the first antenna, the first transmit circuit comprising:
      a first power amplifier coupled to the first antenna; and
      a third mixer coupled to the first power amplifier;
   a second transmit circuit coupled to the second antenna, the second transmit circuit comprising:
      a second power amplifier coupled to the second antenna; and
      a fourth mixer coupled to the second power amplifier.
19. The system of clause 18, further comprising:
   a first antenna coupler coupling the first transmit circuit and the first receive circuit to the first antenna; and
   a second antenna coupler coupling the second transmit circuit and the second receive circuit to the second antenna.
20. The system of clause 18 or 19, further comprising a controller configured to:
   in a first configuration, cause the first multiplexer to select the first LO signal and cause the second multiplexer to select the first LO, or cause the first multiplexer to select the second LO signal and the second multiplexer to select the second LO signal; and
   in a second configuration, cause the first multiplexer to select the first LO signal and cause the second multiplexer to select the second LO signal.
21. The system of any one of clauses 18 to 20, wherein:
   in the first configuration, the first receive circuit is configured to receive a first copy of a first receive radio frequency (RF) signal via the first antenna; and
   in the first configuration, the second receive circuit is configured to receive a second copy of the first receive RF signal via the second antenna.
22. The system of clause 21, wherein:
   in the second configuration, the first transmit circuit is configured to transmit a first transmit RF signal for a first subscriber via the first antenna;
   in the second configuration, the first receive circuit or the second receive circuit is configured to receive a second receive RF signal for the first subscriber via the first antenna;
   in the second configuration, the second transmit circuit is configured to transmit a second transmit RF signal for a second subscriber via the second antenna; and
   in the second configuration, the first receive circuit or the second receive circuit is configured to receive a third receive RF signal for the second subscriber via the second antenna.
23. The system of clause 22, wherein the first subscriber is associated with a first subscriber identity module (SIM) and the second subscriber is associated with a second SIM.
24. The system of clause 22 or 23, further comprising a primary receive port coupled to the first receive circuit and a diversity receive port coupled to the second receive circuit.
25. A method of operating a wireless device comprising:
   in a first configuration of a transceiver of the wireless device,
      receiving a first copy of a first radio frequency (RF) signal via a first antenna;
      receiving a second copy of the first RF signal via a second antenna; and
      generating a combined signal based on the first copy of the first RF signal and the second copy of the first RF signal; and
   in a second configuration of the transceiver,
      receiving a second RF signal via the first antenna;
      receiving a third RF signal via the second antenna;
      recovering data or control information for a first subscriber based on the second RF signal; and
      recovering data or control information for a second subscriber based on the third RF signal.
26. The method of clause 25, wherein the first subscriber is associated with a first subscriber identity module (SIM) and the second subscriber is associated with a second SIM.
27. The method of clause 25 or 26, wherein the second RF signal is received from a first base station, and the third RF signal is received from a second base station.
28. The method of any one of clauses 25 to 27, further comprising:
   converting the first copy of the first RF signal into a first baseband signal; and
   converting the second copy of the first RF signal into a second baseband signal, wherein generating the combined signal comprises combining the first baseband signal and the second baseband signal.
29. The method of clause 28, wherein combining the first baseband signal and the second baseband signal comprises combining the first baseband signal and the second baseband signal using one or more of maximal ratio combining, minimum mean square error, equal-gain combining, and active null steering.
30. The method of clause 28 or 29, wherein:
   converting the first copy of the first RF signal into the first baseband signal comprises mixing the first copy of the first RF signal with a first local oscillator (LO) signal using a first mixer; and
   converting the second copy of the first RF signal into the second baseband signal comprises mixing the second copy of the first RF signal with the first LO signal using a second mixer.
31. The method of any one of clauses 28 to 30, further comprising:
   converting the second RF signal into a third baseband signal; and
   converting the third RF signal into a fourth baseband signal.
32. The method of clause 31, wherein:
   recovering the data or the control information for the first subscriber comprises
   recovering the data or the control information for the first subscriber based on the third baseband signal; and
   recovering the data or the control information for the second subscriber comprises recovering the data or the control information for the second subscriber based on the fourth baseband signal.
33. The method of clause 31 or 32, wherein:
converting the first copy of the first RF signal into the first baseband signal comprises mixing the first copy of the first RF signal with a first local oscillator (LO) signal using a first mixer;
   converting the second copy of the first RF signal into the second baseband signal comprises mixing the second copy of the first RF signal with the first LO signal using a second mixer;
   converting the second RF signal into the third baseband signal comprises mixing the second RF signal with the first LO signal using the first mixer; and
   converting the third RF signal into the fourth baseband signal comprises mixing the third RF signal with a second LO signal using the second mixer.
34. An apparatus, comprising:
   means for receiving a first copy of a first radio frequency (RF) signal via a first antenna;
   means for receiving a second copy of the first RF signal via a second antenna; and
   means for generating a combined signal based on the first copy of the first RF signal and the second copy of the first RF signal;
   means for receiving a second RF signal via the first antenna;
   means for receiving a third RF signal via the second antenna;
means for recovering data or control information for a first subscriber based on the second RF signal; and
means for recovering data or control information for a second subscriber based on the third RF signal.
35. A system for wireless communications, comprising:
   a first receive circuit coupled to a first antenna, wherein the first receive circuit is configured to receive a first copy of a first radio frequency (RF) signal via the first antenna, and receive a second RF signal via the first antenna;
   a second receive circuit coupled to a second antenna, wherein the second receive circuit is configured to receive a second copy of the first RF signal via the second antenna, and receive a third RF signal via the second antenna; and
   a processor coupled to the first receive circuit and the second receive circuit, wherein the processor is configured to generate a combined signal based on the first copy of the first RF signal and the second copy of the first RF signal, recover data or control information for a first subscriber based on the second RF signal, and a recover data or control information for a second subscriber based on the third RF signal.
36. The system of clause 35, wherein the first subscriber is associated with a first subscriber identity module (SIM) and the second subscriber is associated with a second SIM.
37. The system of clause 36, wherein:
   the first receive circuit is configured to convert the first copy of the first RF signal into a first baseband signal;
   the second receive circuit is configured to convert the second copy of the first RF signal into a second baseband signal; and
the processor is configured to combine the first baseband signal and the second baseband signal to generate the combined signal.
38. The system of clause 37, wherein the processor is configured to combine the first baseband signal and the second baseband signal using one or more of maximal ratio combining, minimum mean square error, equal-gain combining, and active null steering.
39. The system of clause 37 or 38, wherein:
   the first receive circuit is configured to convert the second RF signal into a third baseband signal;
   the second receive circuit is configured to convert the third RF signal into a fourth baseband signal; and
   the processor is configured to recover the data or the control information for the first subscriber based on the third baseband signal, and recover the data or the control information for the second subscriber based on the fourth baseband signal.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a DC ground or an AC ground, and thus the term “ground” covers both possibilities.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A system for wireless communications, comprising:
a first receive circuit coupled to a first antenna, the first receive circuit comprising:
a first low-noise amplifier coupled to the first antenna; and
a first mixer coupled to the first low-noise amplifier;
a second receive circuit coupled to a second antenna, the second receive circuit comprising:
a second low-noise amplifier coupled to the second antenna; and
a second mixer coupled to the second low-noise amplifier;
a first frequency synthesizer configured to generate a first local oscillator (LO) signal;
a second frequency synthesizer configured to generate a second LO signal;
a first multiplexer configured to selectively couple the first LO signal or the second LO signal to the first mixer; and
a second multiplexer configured to selectively couple the first LO signal or the second LO signal to the second mixer.

2. The system of claim 1, further comprising a controller configured to:
in a first configuration, cause the first multiplexer to select the first LO signal and cause the second multiplexer to select the first LO; and
in a second configuration, cause the first multiplexer to select the first LO signal and cause the second multiplexer to select the second LO signal.

3. The system of claim 2, further comprising a processor coupled to the first receive circuit and the second receive circuit, wherein the processor is configured to:
in the first configuration,
receive a first baseband signal from the first receive circuit and receive a second baseband signal from the second receive circuit; and
combine the first baseband signal and the second baseband signal into a combined signal.

4. The system of claim 3, wherein the processor is configured to combine the first baseband signal and the second baseband signal using one or more of maximal ratio combining, minimum mean square error, equal-gain combining, and active null steering.

5. The system of claim 3, wherein the processor is further configured to:
in the second configuration,
receive a third baseband signal from the first receive circuit and receive a fourth baseband signal from the second receive circuit;
recover data or control information for a first subscriber based on the third baseband signal; and
recover data or control information for a second subscriber based on the fourth baseband signal.

6. The system of claim 5, wherein the first subscriber is associated with a first subscriber identity module (SIM) and the second subscriber is associated with a second SIM.

7. The system of claim 2, further comprising:
a first gating circuit coupled between the first frequency synthesizer and a first input of the first multiplexer;
a second gating circuit coupled between the second frequency synthesizer and a second input of the first multiplexer;
a third gating circuit coupled between the first frequency synthesizer and a first input of the second multiplexer; and
a fourth gating circuit coupled between the second frequency synthesizer and a second input of the second multiplexer.

8. The system of claim 7, wherein the controller is configured to:
in the first configuration, cause the first gating circuit to pass the first LO signal to the first input of the first multiplexer, cause the second gating circuit to gate the second LO signal, cause the third gating circuit to pass the first LO signal to the first input of the second multiplexer, and cause the fourth gating circuit to gate the second LO signal; and
in the second configuration, cause the first gating circuit to pass the first LO signal to the first input of the first multiplexer, cause the second gating circuit to gate the second LO signal, cause the third gating circuit to gate the first LO signal, and cause the fourth gating circuit to pass the second LO signal to the second input of the second multiplexer.

9. The system of claim 7, wherein each of the first gating circuit, the second gating circuit, the third gating circuit, and the fourth gating circuit comprises a respective AND gate.

10. The system of claim 1, further comprising:
a first transmit circuit coupled to the first antenna, the first transmit circuit comprising:
a first power amplifier coupled to the first antenna; and
a third mixer coupled to the first power amplifier;
a second transmit circuit coupled to a third antenna, the second transmit circuit comprising:
a second power amplifier coupled to the third antenna; and
a fourth mixer coupled to the second power amplifier.

11. The system of claim 10, further comprising a controller configured to:
in a first configuration, cause the first multiplexer to select the first LO signal and cause the second multiplexer to select the first LO, or cause the first multiplexer to select the second LO signal and the second multiplexer to select the second LO signal; and
in a second configuration, cause the first multiplexer to select the first LO signal and cause the second multiplexer to select the second LO signal.

12. The system of claim 11, wherein:
in the first configuration, the first receive circuit is configured to receive a first copy of a first receive radio frequency (RF) signal via the first antenna; and
in the first configuration, the second receive circuit is configured to receive a second copy of the first receive RF signal via the second antenna.

13. The system of claim 12, wherein:
in the second configuration, the first transmit circuit is configured to transmit a first transmit RF signal for a first subscriber via the first antenna;
in the second configuration, the first receive circuit is configured to receive a second receive RF signal for the first subscriber via the first antenna;
in the second configuration, the second transmit circuit is configured to transmit a second transmit RF signal for a second subscriber via the third antenna; and
in the second configuration, the second receive circuit is configured to receive a third receive RF signal for the second subscriber via the second antenna.

14. The system of claim 13, wherein the first subscriber is associated with a first subscriber identity module (SIM) and the second subscriber is associated with a second SIM.

15. The system of claim 1, further comprising:
a first transmit circuit coupled to the first antenna, the first transmit circuit comprising:
a first power amplifier coupled to the first antenna; and
a third mixer coupled to the first power amplifier;
a second transmit circuit coupled to the second antenna, the second transmit circuit comprising:
a second power amplifier coupled to the second antenna; and
a fourth mixer coupled to the second power amplifier.

16. The system of claim 15, further comprising:
a first antenna coupler coupling the first transmit circuit and the first receive circuit to the first antenna; and
a second antenna coupler coupling the second transmit circuit and the second receive circuit to the second antenna.

17. The system of claim 15, further comprising a controller configured to:
in a first configuration, cause the first multiplexer to select the first LO signal and cause the second multiplexer to select the first LO, or cause the first multiplexer to select the second LO signal and the second multiplexer to select the second LO signal; and
in a second configuration, cause the first multiplexer to select the first LO signal and cause the second multiplexer to select the second LO signal.

18. The system of claim 17, wherein:
in the first configuration, the first receive circuit is configured to receive a first copy of a first receive radio frequency (RF) signal via the first antenna; and
in the first configuration, the second receive circuit is configured to receive a second copy of the first receive RF signal via the second antenna.

19. The system of claim 18, wherein:
in the second configuration, the first transmit circuit is configured to transmit a first transmit RF signal for a first subscriber via the first antenna;
in the second configuration, the first receive circuit or the second receive circuit is configured to receive a second receive RF signal for the first subscriber via the first antenna;
in the second configuration, the second transmit circuit is configured to transmit a second transmit RF signal for a second subscriber via the second antenna; and
in the second configuration, the first receive circuit or the second receive circuit is configured to receive a third receive RF signal for the second subscriber via the second antenna.

20. The system of claim 19, wherein the first subscriber is associated with a first subscriber identity module (SIM) and the second subscriber is associated with a second SIM.

21. A method of operating a wireless device comprising:
in a first configuration of a transceiver of the wireless device,
receiving a first copy of a first radio frequency (RF) signal via a first antenna;
receiving a second copy of the first RF signal via a second antenna; and
generating a combined signal based on the first copy of the first RF signal and the second copy of the first RF signal; and
in a second configuration of the transceiver,
receiving a second RF signal via the first antenna;
receiving a third RF signal via the second antenna;
recovering data or control information for a first subscriber based on the second RF signal; and
recovering data or control information for a second subscriber based on the third RF signal.

22. The method of claim 21, wherein the first subscriber is associated with a first subscriber identity module (SIM) and the second subscriber is associated with a second SIM.

23. The method of claim 21, further comprising:
converting the first copy of the first RF signal into a first baseband signal; and
converting the second copy of the first RF signal into a second baseband signal, wherein generating the combined signal comprises combining the first baseband signal and the second baseband signal.

24. The method of claim 23, wherein combining the first baseband signal and the second baseband signal comprises combining the first baseband signal and the second baseband signal using one or more of maximal ratio combining, minimum mean square error, equal-gain combining, and active null steering.

25. The method of claim 23, wherein:
converting the first copy of the first RF signal into the first baseband signal comprises mixing the first copy of the first RF signal with a first local oscillator (LO) signal using a first mixer; and
converting the second copy of the first RF signal into the second baseband signal comprises mixing the second copy of the first RF signal with the first LO signal using a second mixer.

26. The method of claim 23, further comprising:
converting the second RF signal into a third baseband signal; and
converting the third RF signal into a fourth baseband signal.

27. The method of claim 26, wherein:
recovering the data or the control information for the first subscriber comprises recovering the data or the control information for the first subscriber based on the third baseband signal; and
recovering the data or the control information for the second subscriber comprises recovering the data or the control information for the second subscriber based on the fourth baseband signal.

28. The method of claim 26, wherein:
converting the first copy of the first RF signal into the first baseband signal comprises mixing the first copy of the first RF signal with a first local oscillator (LO) signal using a first mixer;
converting the second copy of the first RF signal into the second baseband signal comprises mixing the second copy of the first RF signal with the first LO signal using a second mixer;
converting the second RF signal into the third baseband signal comprises mixing the second RF signal with the first LO signal using the first mixer; and
converting the third RF signal into the fourth baseband signal comprises mixing the third RF signal with a second LO signal using the second mixer.

29. An apparatus, comprising:
means for receiving a first copy of a first radio frequency (RF) signal via a first antenna;
means for receiving a second copy of the first RF signal via a second antenna; and
means for generating a combined signal based on the first copy of the first RF signal and the second copy of the first RF signal;
means for receiving a second RF signal via the first antenna;
means for receiving a third RF signal via the second antenna;
means for recovering data or control information for a first subscriber based on the second RF signal; and
means for recovering data or control information for a second subscriber based on the third RF signal.

30. A system for wireless communications, comprising:
a first receive circuit coupled to a first antenna, wherein the first receive circuit is configured to receive a first copy of a first radio frequency (RF) signal via the first antenna, and receive a second RF signal via the first antenna;
a second receive circuit coupled to a second antenna, wherein the second receive circuit is configured to receive a second copy of the first RF signal via the second antenna, and receive a third RF signal via the second antenna; and
a processor coupled to the first receive circuit and the second receive circuit, wherein the processor is configured to generate a combined signal based on the first copy of the first RF signal and the second copy of the first RF signal, recover data or control information for a first subscriber based on the second RF signal, and a recover data or control information for a second subscriber based on the third RF signal.
